(19) United States
(12) Patent Application Publication
(10) Pub. No.: US 2024/0094269 A1
(43) Pub. Date: Mar. 21, 2024

(54) SENSOR MEASUREMENT CORRECTION BASED ON EMPIRICAL DATA

(71) Applicant: QUALCOMM Incorporated, San Diego, CA (US)

(72) Inventors: Krishna Sai Anirudh KATAMREDDY, San Diego, CA (US); Suresh SHENOY, San Diego, CA (US); Kevin Bradley CITTERELLE, Leander, TX (US)

(21) Appl. No.: 17/933,824

(22) Filed: Sep. 20, 2022

(51) Int. Cl. G01R 21/06; G06N 20/00

(52) U.S. Cl. CPC G01R 21/06; G06N 20/00

(57) ABSTRACT

In an aspect, measurement processing circuitry may obtain, from a sensor, a first measured value of a measured object, the first measured value corresponding to a first power consumption level of the measured object at a first time point. The measurement processing circuitry may obtain, from the sensor, one or more second measured values of the measured object, the one or more second measured values corresponding to one or more second power consumption levels of the measured object at one or more second time points earlier than the first time point. The measurement processing circuitry may determine a corrected value based on the first measured value and the one or more second measured values, the corrected value representing the first power consumption level of the measured object at the first time point.

### BACKGROUND OF THE DISCLOSURE

### 1. Field of the Disclosure

Aspects of the disclosure relate generally to sensor measurement correction for a measured value of a measured object.

### 2. Description of the Related Art

With the development of technology, computing devices play an important role in providing users various types of services and convenient access to information. For example, computer devices can be configured as user terminals, base stations, and network entities in a wireless communication system. Users usually demand the computing devices to offer powerful performance while operate under certain power consumption limitations or power budgets. The power consumption level of a computing device may be evaluated and/or measured by a sensor disposed in the computing device, such as a current sensor or a voltage sensor. The effectiveness of the performance and power management of the computer device may depend on the accuracy of the measured power consumption level.

Conventional systems use current sensing for peak power management in mobile devices having stringent end-to-end timing requirements. However, the conventional systems are prone to errors such as over or under throttling, instability, etc. Accordingly, there is a need for systems, apparatuses and methods that overcome the deficiencies of conventional designs including the methods, systems and apparatuses for single and multi-die packages with sealed enclosures provided herein in the following disclosure.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, a method of measurement correction includes obtaining, from a sensor, a first measured value of a measured object, the first measured value corresponding to a first power consumption level of the measured object at a first time point; obtaining, from the sensor, one or more second measured values of the measured object, the one or more second measured values corresponding to one or more second power consumption levels of the measured object at one or more second time points earlier than the first time point; and determining, by measurement processing circuitry, a corrected value based on the first measured value and the one or more second measured values, the corrected value representing the first power consumption level of the measured object at the first time point.

In an aspect, a method of measurement correction includes obtaining, from a sensor, a first measured value of a measured object, the first measured value corresponding to a first power consumption level of the measured object at a first time point; obtaining, from the sensor, one or more second measured values of the measured object, the one or more second measured values corresponding to one or more second power consumption levels of the measured object at one or more second time points earlier than the first time point; obtaining, from measurement processing circuitry, a corrected value that is determined based on the first measured value and the one or more second measured values, the corrected value representing the first power consumption level of the measured object at the first time point; training a machine learning model for determining an updated set of measurement processing coefficients of the measurement processing circuitry, the training the machine learning model being based on training input data and training reference data, the training input data being based on the first measured value, the one or more second measured values, the corrected value, a value derived from the measured values, or a combination thereof, and the training reference data being based on a ground truth value of the first power consumption level; and configuring the measurement processing circuitry based on the updated set of measurement processing coefficients after the machine learning model is trained based on the training input data and the training reference data.

In an aspect, a computing device includes a memory; and at least one processor communicatively coupled to the memory, the at least one processor configured to: obtain, from a sensor, a first measured value of a measured object, the first measured value corresponding to a first power consumption level of the measured object at a first time point; obtain, from the sensor, one or more second measured values of the measured object, the one or more second measured values corresponding to one or more second power consumption levels of the measured object at one or more second time points earlier than the first time point; and determine a corrected value based on the first measured value and the one or more second measured values, the corrected value representing the first power consumption level of the measured object at the first time point.

In an aspect, a computing device includes a memory; and at least one processor communicatively coupled to the memory, the at least one processor configured to: obtain, from a sensor, a first measured value of a measured object, the first measured value corresponding to a first power consumption level of the measured object at a first time point; obtain, from the sensor, one or more second measured values of the measured object, the one or more second measured values corresponding to one or more second power consumption levels of the measured object at one or more second time points earlier than the first time point; obtain, from measurement processing circuitry, a corrected value that is determined based on the first measured value and the one or more second measured values, the corrected value representing the first power consumption level of the measured object at the first time point; train a machine learning model for determining an updated set of measurement processing coefficients of the measurement processing circuitry, the machine learning model being trained based on training input data and training reference data, the training input data being based on the first measured value, the one or more second measured values, the corrected value, a value derived from the measured values, or a combination thereof, and the training reference data being based on a ground truth value of the first power consumption level; and configure the measurement processing circuitry based on the updated set of measurement processing coefficients after the machine learning model is trained based on the training input data and the training reference data.

In an aspect, a computing device includes means for obtaining, from a sensor, a first measured value of a measured object, the first measured value corresponding to a first power consumption level of the measured object at a first time point; means for obtaining, from the sensor, one or more second measured values of the measured object, the one or more second measured values corresponding to one or more second power consumption levels of the measured object at one or more second time points earlier than the first time point; and means for determining a corrected value based on the first measured value and the one or more second measured values, the corrected value representing the first power consumption level of the measured object at the first time point.

In an aspect, a computing device includes means for obtaining, from a sensor, a first measured value of a measured object, the first measured value corresponding to a first power consumption level of the measured object at a first time point; means for obtaining, from the sensor, one or more second measured values of the measured object, the one or more second measured values corresponding to one or more second power consumption levels of the measured object at one or more second time points earlier than the first time point; means for obtaining, from measurement processing circuitry, a corrected value that is determined based on the first measured value and the one or more second measured values, the corrected value representing the first power consumption level of the measured object at the first time point; means for training a machine learning model for determining an updated set of measurement processing coefficients of the measurement processing circuitry, the training the machine learning model being based on training input data and training reference data, the training input data being based on the first measured value, the one or more second measured values, the corrected value, a value derived from the measured values, or a combination thereof, and the training reference data being based on a ground truth value of the first power consumption level; and means for configuring the measurement processing circuitry based on the updated set of measurement processing coefficients after the machine learning model is trained based on the training input data and the training reference data.

In an aspect, a non-transitory computer-readable medium stores computer-executable instructions that, when executed by a computing device, cause the computing device to: obtain, from a sensor, a first measured value of a measured object, the first measured value corresponding to a first power consumption level of the measured object at a first time point; obtain, from the sensor, one or more second measured values of the measured object, the one or more second measured values corresponding to one or more second power consumption levels of the measured object at one or more second time points earlier than the first time point; and determine, by measurement processing circuitry, a corrected value based on the first measured value and the one or more second measured values, the corrected value representing the first power consumption level of the measured object at the first time point.

In an aspect, a non-transitory computer-readable medium stores computer-executable instructions that, when executed by a computing device, cause the computing device to: obtain, from a sensor, a first measured value of a measured object, the first measured value corresponding to a first power consumption level of the measured object at a first time point; obtain, from the sensor, one or more second measured values of the measured object, the one or more second measured values corresponding to one or more second power consumption levels of the measured object at one or more second time points earlier than the first time point; obtain, from measurement processing circuitry, a corrected value that is determined based on the first measured value and the one or more second measured values, the corrected value representing the first power consumption level of the measured object at the first time point; train a machine learning model for determining an updated set of measurement processing coefficients of the measurement processing circuitry, the machine learning model being trained based on training input data and training reference data, the training input data being based on the first measured value, the one or more second measured values, the corrected value, a value derived from the measured values, or a combination thereof, and the training reference data being based on a ground truth value of the first power consumption level; and configure the measurement processing circuitry based on the updated set of measurement processing coefficients after the machine learning model is trained based on the training input data and the training reference data.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIG. 1 illustrates an example wireless communications system, according to aspects of the disclosure.

FIGS. 2A, 2B, and 2C are simplified block diagrams of several sample aspects of components that may be employed in a user equipment (UE), abase station, and a network entity, respectively, and configured to support communications as taught herein.

FIG. 3 is a functional block diagram illustrating a power management system in a computing device, according to aspects of the disclosure.

FIG. 4 illustrates an example neural network, according to aspects of the disclosure.

FIG. 5 is a diagram illustrating operations for obtaining a measured value, operations for obtaining a corrected value 504 based on a set of measurement processing coefficients, and operations for determining the set of measurement processing coefficients, according to aspects of the disclosure.

FIG. 6 is a graph illustrating a curve representing measured values output by the sensor in FIG. 5 and a curve representing ground truth values measured and provide by an external instrument, according to aspects of the disclosure.

FIG. 7 illustrates an example method of measurement correction during at least a correction inference phase, according to aspects of the disclosure.

FIG. 8 illustrates an example method of measurement correction during at least a model training phase, according to aspects of the disclosure.

### DETAILED DESCRIPTION

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

As used herein, the terms “user equipment” (UE) and “base station” are not intended to be specific or otherwise limited to any particular radio access technology (RAT), unless otherwise noted. In general, a UE may be any wireless communication device (e.g., a mobile phone, router, tablet computer, laptop computer, consumer asset locating device, wearable (e.g., smartwatch, glasses, augmented reality (AR)/virtual reality (VR) headset, etc.), vehicle (e.g., automobile, motorcycle, bicycle, etc.), Internet of Things (IoT) device, etc.) used by a user to communicate over a wireless communications network. A UE may be mobile or may (e.g., at certain times) be stationary, and may communicate with a radio access network (RAN). As used herein, the term “UE” may be referred to interchangeably as an “access terminal” or “AT,” a “client device,” a “wireless device,” a “subscriber device,” a “subscriber terminal,” a “subscriber station,” a “user terminal” or “UT,” a “mobile device,” a “mobile terminal,” a “mobile station,” or variations thereof.

Generally, UEs can communicate with a core network via a RAN, and through the core network the UEs can be connected with external networks such as the Internet and with other UEs. Of course, other mechanisms of connecting to the core network and/or the Internet are also possible for the UEs, such as over wired access networks, wireless local area network (WLAN) networks (e.g., based on the Institute of Electrical and Electronics Engineers (IEEE) 802.11 specification, etc.) and so on.

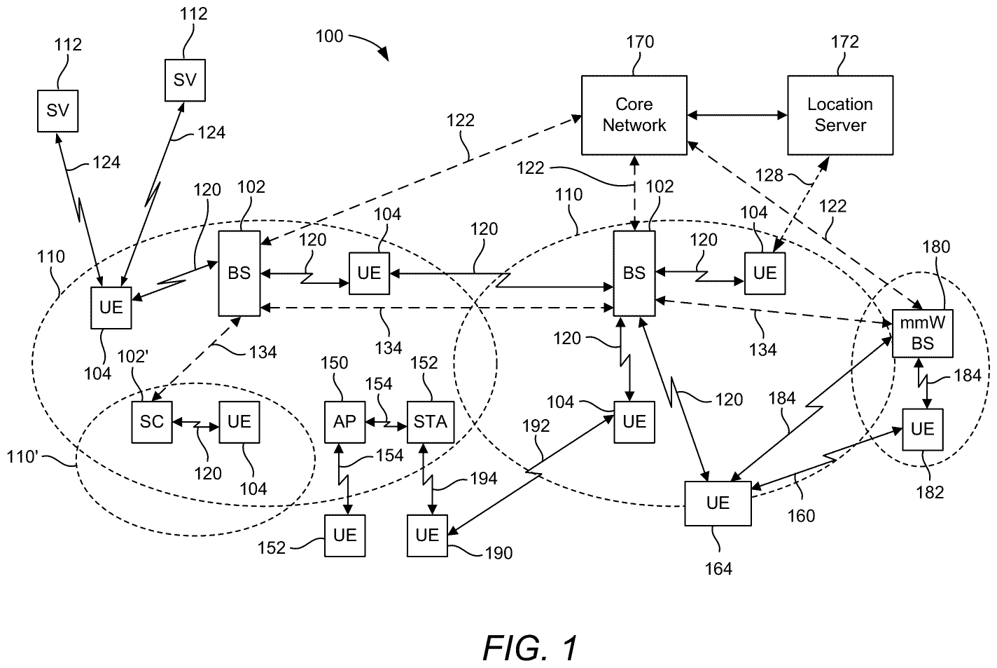

FIG. 1 illustrates an example wireless communications system 100, according to aspects of the disclosure. The wireless communications system 100 (which may also be referred to as a wireless wide area network (WWAN)) may include various base stations 102 (labeled “BS”) and various UEs 104. The base stations 102 may include macro cell base stations (high power cellular base stations) and/or small cell base stations (low power cellular base stations). In an aspect, the macro cell base stations may include eNBs and/or ng-eNBs where the wireless communications system 100 corresponds to an LTE network, or gNBs where the wireless communications system 100 corresponds to a NR network, or a combination of both, and the small cell base stations may include femtocells, picocells, microcells, etc.

The base stations 102 may collectively form a RAN and interface with a core network 170 (e.g., an evolved packet core (EPC) or a 5G core (5GC)) through backhaul links 122, and through the core network 170 to one or more location servers 172 (e.g., a location management function (LMF) or a secure user plane location (SUPL) location platform (SLP)). The location server(s) 172 may be part of core network 170 or may be external to core network 170. A location server 172 may be integrated with a base station 102. A UE 104 may communicate with a location server 172 directly or indirectly. For example, a UE 104 may communicate with a location server 172 via the base station 102 that is currently serving that UE 104. A UE 104 may also communicate with a location server 172 through another path, such as via an application server (not shown), via another network, such as via a wireless local area network (WLAN) access point (AP) (e.g., AP 150 described below), and so on. For signaling purposes, communication between a UE 104 and a location server 172 may be represented as an indirect connection (e.g., through the core network 170, etc.) or a direct connection (e.g., as shown via direct connection 128), with the intervening nodes (if any) omitted from a signaling diagram for clarity.

The base stations 102 may wirelessly communicate with the UEs 104. Each of the base stations 102 may provide communication coverage for a respective geographic coverage area 110. While neighboring macro cell base station 102 geographic coverage areas 110 may partially overlap (e.g., in a handover region), some of the geographic coverage areas 110 may be substantially overlapped by a larger geographic coverage area 110. For example, a small cell base station 102′ (labeled “SC” for “small cell”) may have a geographic coverage area 110′ that substantially overlaps with the geographic coverage area 110 of one or more macro cell base stations 102. A network that includes both small cell and macro cell base stations may be known as a heterogeneous network. A heterogeneous network may also include home eNBs (HeNBs), which may provide service to a restricted group known as a closed subscriber group (CSG).

The wireless communications system 100 may further include a wireless local area network (WLAN) access point (AP) 150 in communication with WLAN stations (STAs) 152 via communication links 154 in an unlicensed frequency spectrum (e.g., 5 GHz). When communicating in an unlicensed frequency spectrum, the WLAN STAs 152 and/or the WLAN AP 150 may perform a clear channel assessment (CCA) or listen before talk (LBT) procedure prior to communicating in order to determine whether the channel is available.

In some aspects, one of the frequencies utilized by the macro cell base stations 102 may be an anchor carrier (or “PCell”) and other frequencies utilized by the macro cell base stations 102 and/or the mmW base station 180 may be secondary carriers (“SCells”). The simultaneous transmission and/or reception of multiple carriers enables the UE 104/182 to significantly increase its data transmission and/or reception rates. For example, two 20 MHz aggregated carriers in a multi-carrier system would theoretically lead to a two-fold increase in data rate (i.e., 40 MHz), compared to that attained by a single 20 MHz carrier.

The wireless communications system 100 may further include a UE 164 that may communicate with a macro cell base station 102 over a communication link 120 and/or the mmW base station 180 over a mmW communication link 184. For example, the macro cell base station 102 may support a PCell and one or more SCells for the UE 164 and the mmW base station 180 may support one or more SCells for the UE 164.

In some cases, the UE 164 and the UE 182 may be capable of sidelink communication. Sidelink-capable UEs (SL-UEs) may communicate with base stations 102 over communication links 120 using the Uu interface (i.e., the air interface between a UE and a base station). SL-UEs (e.g., UE 164, UE 182) may also communicate directly with each other over a wireless sidelink 160 using the PC5 interface (i.e., the air interface between sidelink-capable UEs). A wireless sidelink (or just “sidelink”) is an adaptation of the core cellular (e.g., LTE, NR) standard that allows direct communication between two or more UEs without the communication needing to go through a base station. Sidelink communication may be unicast or multicast, and may be used for device-to-device (D2D) media-sharing, vehicle-to-vehicle (V2V) communication, vehicle-to-everything (V2X) communication (e.g., cellular V2X (cV2X) communication, enhanced V2X (eV2X) communication, etc.), emergency rescue applications, etc. One or more of a group of SL-UEs utilizing sidelink communications may be within the geographic coverage area 110 of a base station 102. Other SL-UEs in such a group may be outside the geographic coverage area 110 of a base station 102 or be otherwise unable to receive transmissions from a base station 102. In some cases, groups of SL-UEs communicating via sidelink communications may utilize a one-to-many (1:M) system in which each SL-UE transmits to every other SL-UE in the group. In some cases, a base station 102 facilitates the scheduling of resources for sidelink communications. In other cases, sidelink communications are carried out between SL-UEs without the involvement of a base station 102.

Note that although FIG. 1 only illustrates two of the UEs as SL-UEs (i.e., UEs 164 and 182), any of the illustrated UEs may be SL-UEs. Further, although only UE 182 was described as being capable of beamforming, any of the illustrated UEs, including UE 164, may be capable of beamforming. Where SL-UEs are capable of beamforming, they may beamform towards each other (i.e., towards other SL-UEs), towards other UEs (e.g., UEs 104), towards base stations (e.g., base stations 102, 180, small cell 102′, access point 150), etc. Thus, in some cases, UEs 164 and 182 may utilize beamforming over sidelink 160.

In the example of FIG. 1, any of the illustrated UEs (shown in FIG. 1 as a single UE 104 for simplicity) may receive signals 124 from one or more Earth orbiting space vehicles (SVs) 112 (e.g., satellites). In an aspect, the SVs 112 may be part of a satellite positioning system that a UE 104 can use as an independent source of location information. A satellite positioning system typically includes a system of transmitters (e.g., SVs 112) positioned to enable receivers (e.g., UEs 104) to determine their location on or above the Earth based, at least in part, on positioning signals (e.g., signals 124) received from the transmitters. Such a transmitter typically transmits a signal marked with a repeating pseudo-random noise (PN) code of a set number of chips. While typically located in SVs 112, transmitters may sometimes be located on ground-based control stations, base stations 102, and/or other UEs 104. A UE 104 may include one or more dedicated receivers specifically designed to receive signals 124 for deriving geo location information from the SVs 112.

In a satellite positioning system, the use of signals 124 can be augmented by various satellite-based augmentation systems (SBAS) that may be associated with or otherwise enabled for use with one or more global and/or regional navigation satellite systems. For example an SBAS may include an augmentation system(s) that provides integrity information, differential corrections, etc., such as the Wide Area Augmentation System (WAAS), the European Geostationary Navigation Overlay Service (EGNOS), the Multi-functional Satellite Augmentation System (MSAS), the Global Positioning System (GPS) Aided Geo Augmented Navigation or GPS and Geo Augmented Navigation system (GAGAN), and/or the like. Thus, as used herein, a satellite positioning system may include any combination of one or more global and/or regional navigation satellites associated with such one or more satellite positioning systems.

In an aspect, SVs 112 may additionally or alternatively be part of one or more non-terrestrial networks (NTNs). In an NTN, an SV 112 is connected to an earth station (also referred to as a ground station, NTN gateway, or gateway), which in turn is connected to an element in a 5G network, such as a modified base station 102 (without a terrestrial antenna) or a network node in a 5GC. This element would in turn provide access to other elements in the 5G network and ultimately to entities external to the 5G network, such as Internet web servers and other user devices. In that way, a UE 104 may receive communication signals (e.g., signals 124) from an SV 112 instead of, or in addition to, communication signals from a terrestrial base station 102.

The wireless communications system 100 may further include one or more UEs, such as UE 190, that connects indirectly to one or more communication networks via one or more device-to-device (D2D) peer-to-peer (P2P) links (referred to as “sidelinks”). In the example of FIG. 1, UE 190 has a D2D P2P link 192 with one of the UEs 104 connected to one of the base stations 102 (e.g., through which UE 190 may indirectly obtain cellular connectivity) and a D2D P2P link 194 with WLAN STA 152 connected to the WLAN AP 150 (through which UE 190 may indirectly obtain WLAN-based Internet connectivity). In an example, the D2D P2P links 192 and 194 may be supported with any well-known D2D RAT, such as LTE Direct (LTE-D), WiFi Direct (WiFi-D), Bluetooth®, and so on.

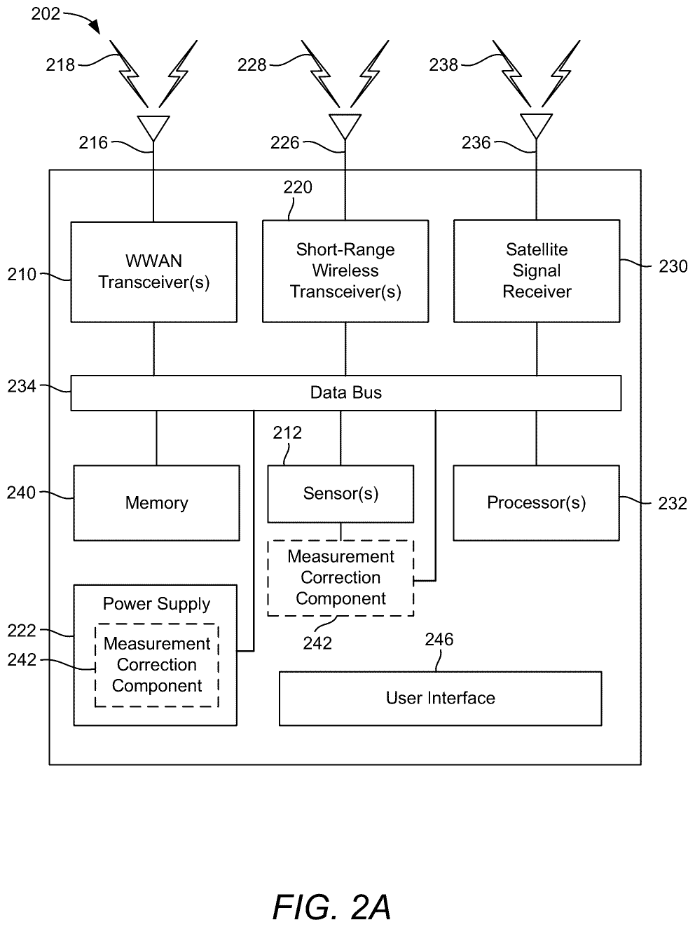

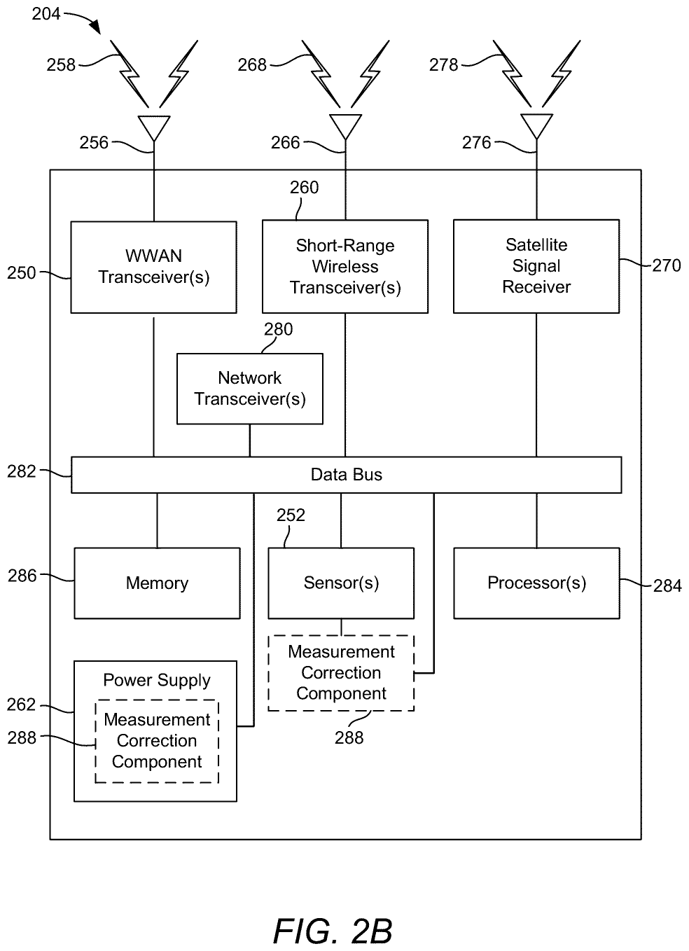

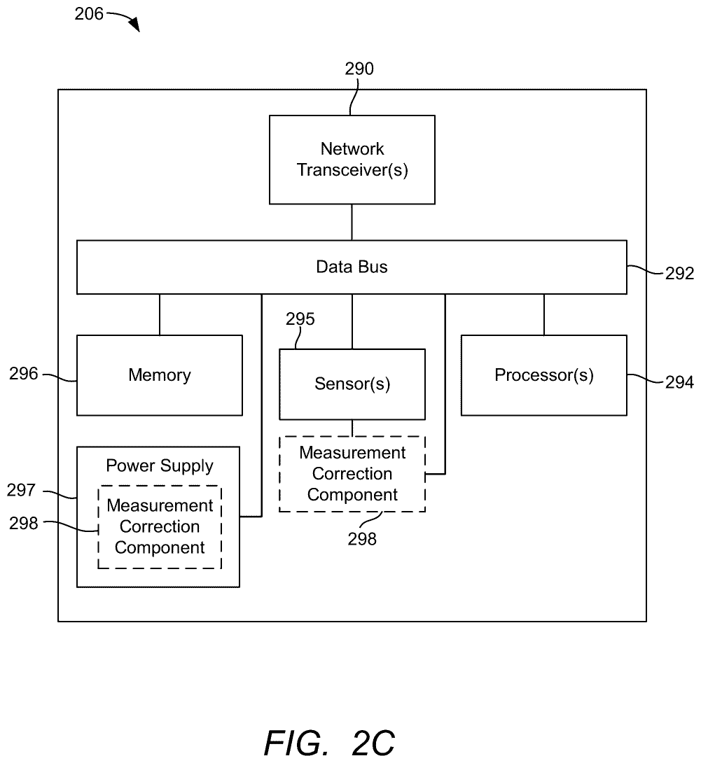

FIGS. 2A, 2B, and 2C illustrate several example components (represented by corresponding blocks) that may be incorporated into a UE 202 (which may correspond to any of the UEs described herein), a base station 204 (which may correspond to any of the base stations described herein), and a network entity 206 (which may correspond to or embody any of the network functions described herein, including the location server 112, or alternatively may be independent from the wireless communications system depicted in FIG. 1, such as a private network) to support the operations described herein. The UE 202, the base station 204, and/or the network entity 206 are used as non-limiting examples of a computing device that is configured to perform various operations of measurement correction described in this disclosure.

It will be appreciated that these components may be implemented in different types of apparatuses in different implementations (e.g., in an ASIC, in a system-on-chip (SoC), etc.). The illustrated components may also be incorporated into other apparatuses in a communication system. For example, other apparatuses in a system may include components similar to those described to provide similar functionality. Also, a given apparatus may contain one or more of the components. For example, an apparatus may include multiple transceiver components that enable the apparatus to operate on multiple carriers and/or communicate via different technologies.

The UE 202 and the base station 204 each include one or more wireless wide area network (WWAN) transceivers 210 and 250, respectively, providing means for communicating (e.g., means for transmitting, means for receiving, means for measuring, means for tuning, means for refraining from transmitting, etc.) via one or more wireless communication networks (not shown), such as an NR network, an LTE network, a GSM network, and/or the like. The WWAN transceivers 210 and 250 may each be connected to one or more antennas 216 and 256, respectively, for communicating with other network nodes, such as other UEs, access points, base stations (e.g., eNBs, gNBs), etc., via at least one designated RAT (e.g., NR, LTE, GSM, etc.) over a wireless communication medium of interest (e.g., some set of time/frequency resources in a particular frequency spectrum).

The WWAN transceivers 210 and 250 may be variously configured for transmitting and encoding signals 218 and 258 (e.g., messages, indications, information, and so on), respectively, and, conversely, for receiving and decoding signals 218 and 258 (e.g., messages, indications, information, pilots, and so on), respectively, in accordance with the designated RAT. Specifically, the WWAN transceivers 210 and 250 may include one or more transmitters for transmitting and encoding signals 218 and 258, respectively. The WWAN transceivers 210 and 250 may include one or more receivers for receiving and decoding signals 218 and 258, respectively.

The UE 202 and the base station 204 each also include, at least in some cases, one or more short-range wireless transceivers 220 and 260, respectively. The short-range wireless transceivers 220 and 260 may be connected to one or more antennas 226 and 266, respectively, and provide means for communicating (e.g., means for transmitting, means for receiving, means for measuring, means for tuning, means for refraining from transmitting, etc.) with other network nodes, such as other UEs, access points, base stations, etc., via at least one designated RAT (e.g., WiFi, LTE-D, Bluetooth®, Zigbee®, Z-Wave®, PC5, dedicated short-range communications (DSRC), wireless access for vehicular environments (WAVE), near-field communication (NFC), ultra-wideband (UWB), etc.) over a wireless communication medium of interest. The short-range wireless transceivers 220 and 260 may be variously configured for transmitting and encoding signals 228 and 268 (e.g., messages, indications, information, and so on), respectively, and, conversely, for receiving and decoding signals 228 and 268 (e.g., messages, indications, information, pilots, and so on), respectively, in accordance with the designated RAT. Specifically, the short-range wireless transceivers 220 and 260 may include one or more transmitters for transmitting and encoding signals 228 and 268, respectively. The short-range wireless transceivers 220 and 260 may include one or more receivers for receiving and decoding signals 228 and 268, respectively. As specific examples, the short-range wireless transceivers 220 and 260 may be WiFi transceivers, Bluetooth® transceivers, Zigbee® and/or Z-Wave® transceivers, NFC transceivers, UWB transceivers, or vehicle-to-vehicle (V2V) and/or vehicle-to-everything (V2X) transceivers.

The UE 202 and the base station 204 also include, at least in some cases, satellite signal receivers 230 and 270. The satellite signal receivers 230 and 270 may be connected to one or more antennas 236 and 276, respectively, and may provide means for receiving and/or measuring satellite positioning/communication signals 238 and 278, respectively. Where the satellite signal receivers 230 and 270 are satellite positioning system receivers, the satellite positioning/communication signals 238 and 278 may be global positioning system (GPS) signals, global navigation satellite system (GLONASS) signals, Galileo signals, Beidou signals, Indian Regional Navigation Satellite System (NAVIC), Quasi-Zenith Satellite System (QZSS), etc. Where the satellite signal receivers 230 and 270 are non-terrestrial network (NTN) receivers, the satellite positioning/communication signals 238 and 278 may be communication signals (e.g., carrying control and/or user data) originating from a 5G network. The satellite signal receivers 230 and 270 may comprise any suitable hardware and/or software for receiving and processing satellite positioning/communication signals 238 and 278, respectively. The satellite signal receivers 230 and 270 may request information and operations as appropriate from the other systems, and, at least in some cases, perform calculations to determine locations of the UE 202 and the base station 204, respectively, using measurements obtained by any suitable satellite positioning system algorithm.

The base station 204 and the network entity 206 each include one or more network transceivers 280 and 290, respectively, providing means for communicating (e.g., means for transmitting, means for receiving, etc.) with other network entities (e.g., other base stations 204, other network entities 206). For example, the base station 204 may employ the one or more network transceivers 280 to communicate with other base stations 204 or network entities 206 over one or more wired or wireless backhaul links. As another example, the network entity 206 may employ the one or more network transceivers 290 to communicate with one or more base station 204 over one or more wired or wireless backhaul links, or with other network entities 206 over one or more wired or wireless core network interfaces.

A transceiver may be configured to communicate over a wired or wireless link. A transceiver (whether a wired transceiver or a wireless transceiver) includes transmitter circuitry and receiver circuitry. A transceiver may be an integrated device (e.g., embodying transmitter circuitry and receiver circuitry in a single device) in some implementations, may comprise separate transmitter circuitry and separate receiver circuitry in some implementations, or may be embodied in other ways in other implementations. The transmitter circuitry and receiver circuitry of a wired transceiver (e.g., network transceivers 280 and 290 in some implementations) may be coupled to one or more wired network interface ports. Wireless transmitter circuitry (e.g., transmitters included in transceivers 210, 220, 250, and 260) may include or be coupled to a plurality of antennas (e.g., antennas 216, 226, 256, 266), such as an antenna array, that permits the respective apparatus (e.g., UE 202, base station 204) to perform transmit “beamforming,” as described herein. Similarly, wireless receiver circuitry (e.g., receivers included in transceivers 210, 220, 250, and 260) may include or be coupled to a plurality of antennas (e.g., antennas 216, 226, 256, 266), such as an antenna array, that permits the respective apparatus (e.g., UE 202, base station 204) to perform receive beamforming, as described herein. In an aspect, the transmitter circuitry and receiver circuitry may share the same plurality of antennas (e.g., antennas 216, 226, 256, 266), such that the respective apparatus can only receive or transmit at a given time, not both at the same time. A wireless transceiver (e.g., WWAN transceivers 210 and 250, short-range wireless transceivers 220 and 260) may also include a network listen module (NLM) or the like for performing various measurements.

As used herein, the various wireless transceivers (e.g., transceivers 210, 220, 250, and 260, and network transceivers 280 and 290 in some implementations) and wired transceivers (e.g., network transceivers 280 and 290 in some implementations) may generally be characterized as “a transceiver,” “at least one transceiver,” or “one or more transceivers.” As such, whether a particular transceiver is a wired or wireless transceiver may be inferred from the type of communication performed. For example, backhaul communication between network devices or servers will generally relate to signaling via a wired transceiver, whereas wireless communication between a UE (e.g., UE 202) and a base station (e.g., base station 204) will generally relate to signaling via a wireless transceiver.

The UE 202, the base station 204, and the network entity 206 also include other components that may be used in conjunction with the operations as disclosed herein. The UE 202, the base station 204, and the network entity 206 include one or more processors 232, 284, and 294, respectively, for providing functionality relating to, for example, wireless communication, and for providing other processing functionality. The processors 232, 284, and 294 may therefore provide means for processing, such as means for determining, means for calculating, means for receiving, means for transmitting, means for indicating, etc. In an aspect, the processors 232, 284, and 294 may include, for example, one or more general purpose processors, multi-core processors, central processing units (CPUs), ASICs, digital signal processors (DSPs), field programmable gate arrays (FPGAs), other programmable logic devices or processing circuitry, or various combinations thereof.

The UE 202, the base station 204, and the network entity 206 include memory circuitry implementing memories 240, 286, and 296 (e.g., each including a memory device), respectively, for maintaining information (e.g., information indicative of reserved resources, thresholds, parameters, and so on). The memories 240, 286, and 296 may therefore provide means for storing, means for retrieving, means for maintaining, etc.

The UE 202, the base station 204, and the network entity 206 include power circuitry configured to implement power supplies 222, 262, and 297, respectively, for powering various components of the UE 202, the base station 204, and the network entity 206, respectively. In some aspects, the power supplies 222, 262, and 297 may receive electrical energy from an external power source and/or an internal power source, converting the electrical energy to regulated voltage sources and/or current sources, and distribute the regulated voltage sources and/or current sources to various power regions or domains in the UE 202, the base station 204, and the network entity 206.

The UE 202, the base station 204, and the network entity 206 may each include one or more sensors 212, 252, and 295 to provide means for sensing or measuring various parameters of operations, including power consumption levels of one or more components or circuit blocks, internal temperatures, external temperatures, environmental illumination levels, and/or environmental noise levels of the UE 202, the base station 204, and the network entity 206, or the like. By way of example, the sensor(s) 212, 252, and 295 may include a current sensor, a voltage sensor, a temperature sensor, a light sensor, an audio sensor, a piezoelectric sensor, and/or any other type of sensor for detecting a power consumption level or an environmental parameter.

The one or more sensors 212 of the UE 202 may be coupled to the one or more processors 232 to provide means for sensing or detecting movement and/or orientation information that is independent of motion data derived from signals received by the one or more WWAN transceivers 210, the one or more short-range wireless transceivers 220, and/or the satellite signal receiver 230. By way of example, the sensor(s) 212 may further include an accelerometer (e.g., a micro-electrical mechanical systems (MEMS) device), a gyroscope, a geomagnetic sensor (e.g., a compass), an altimeter (e.g., a barometric pressure altimeter), and/or any other type of movement detection sensor. Moreover, the sensor(s) 212 may include a plurality of different types of devices and combine their outputs in order to provide motion information. For example, the sensor(s) 212 may use a combination of a multi-axis accelerometer and orientation sensors to provide the ability to compute positions in two-dimensional (2D) and/or three-dimensional (3D) coordinate systems.

In some cases, the UE 202, the base station 204, and the network entity 206 may include measurement correction component 242, 288, and 298, respectively. The measurement correction component 242, 288, and 298 may be part of the respective power management integrated circuit (PMIC) or part of the respective power distribution system of the UE 202, the base station 204, and the network entity 206. In some aspects, the measurement correction component 242, 288, and 298 may be hardware circuits that are embedded in or coupled to the power supplies 222, 262, and 297. In other aspects, the measurement correction component 242, 288, and 298 may be external to the power supplies 222, 262, and 297. FIG. 2A illustrates possible locations of the measurement correction component 242, which may be, for example, part of the power supply 222, a standalone component, or a combination thereof. FIG. 2B illustrates possible locations of the measurement correction component 288, which may be, for example, part of the power supply 262, a standalone component, or a combination thereof. FIG. 2C illustrates possible locations of the measurement correction component 298, which may be, for example, part of the power supply 297, a standalone component, or a combination thereof. In some aspects, the measurement correction component 242, 288, and 298 can be connected to the output of the sensors 212, 252, and 295. In some aspects, every sensor can have its own measurement correction component.

In addition, the UE 202 includes a user interface 246 providing means for providing indications (e.g., audible and/or visual indications) to a user and/or for receiving user input (e.g., upon user actuation of a sensing device such a keypad, a touch screen, a microphone, and so on). Although not shown, the base station 204 and the network entity 206 may also include user interfaces.

Referring to the one or more processors 284 in more detail, in the downlink, IP packets from the network entity 206 may be provided to the processor 284. The one or more processors 284 may implement functionality for an RRC layer, a packet data convergence protocol (PDCP) layer, a radio link control (RLC) layer, and a medium access control (MAC) layer. The one or more processors 284 may provide RRC layer functionality associated with broadcasting of system information (e.g., master information block (MIB), system information blocks (SIBs)), RRC connection control (e.g., RRC connection paging, RRC connection establishment, RRC connection modification, and RRC connection release), inter-RAT mobility, and measurement configuration for UE measurement reporting; PDCP layer functionality associated with header compression/decompression, security (ciphering, deciphering, integrity protection, integrity verification), and handover support functions; RLC layer functionality associated with the transfer of upper layer PDUs, error correction through automatic repeat request (ARQ), concatenation, segmentation, and reassembly of RLC service data units (SDUs), re-segmentation of RLC data PDUs, and reordering of RLC data PDUs; and MAC layer functionality associated with mapping between logical channels and transport channels, scheduling information reporting, error correction, priority handling, and logical channel prioritization.

The transmitter and the receiver of the WWAN transceiver 250 may implement Layer-1 (L1) functionality associated with various signal processing functions. Layer-1, which includes a physical (PHY) layer, may include error detection on the transport channels, forward error correction (FEC) coding/decoding of the transport channels, interleaving, rate matching, mapping onto physical channels, modulation/demodulation of physical channels, and MIMO antenna processing. The transmitter of the WWAN transceiver 250 can handle mapping to signal constellations based on various modulation schemes (e.g., binary phase-shift keying (BPSK), quadrature phase-shift keying (QPSK), M-phase-shift keying (M-PSK), M-quadrature amplitude modulation (M-QAM)). The coded and modulated symbols may then be split into parallel streams. Each stream may then be mapped to an orthogonal frequency division multiplexing (OFDM) subcarrier, multiplexed with a reference signal (e.g., pilot) in the time and/or frequency domain, and then combined together using an inverse fast Fourier transform (IFFT) to produce a physical channel carrying a time domain OFDM symbol stream. The OFDM symbol stream is spatially precoded to produce multiple spatial streams. Channel estimates from a channel estimator may be used to determine the coding and modulation scheme, as well as for spatial processing. The channel estimate may be derived from a reference signal and/or channel condition feedback transmitted by the UE 202. Each spatial stream may then be provided to one or more different antennas 256. The transmitter of the WWAN transceiver 250 may modulate an RF carrier with a respective spatial stream for transmission.

At the UE 202, the receiver of the WWAN transceiver 210 receives a signal through its respective antenna(s) 216. The receiver of the WWAN transceiver 210 recovers information modulated onto an RF carrier and provides the information to the one or more processors 232. The transmitter and the receiver of the WWAN transceiver 210 implement Layer-1 functionality associated with various signal processing functions. The receiver of the WWAN transceiver 210 may perform spatial processing on the information to recover any spatial streams destined for the UE 202. If multiple spatial streams are destined for the UE 202, they may be combined by the receiver of the WWAN transceiver 210 into a single OFDM symbol stream. The receiver of the WWAN transceiver 210 then converts the OFDM symbol stream from the time-domain to the frequency domain using a fast Fourier transform (FFT). The frequency domain signal comprises a separate OFDM symbol stream for each subcarrier of the OFDM signal. The symbols on each subcarrier, and the reference signal, are recovered and demodulated by determining the most likely signal constellation points transmitted by the base station 204. These soft decisions may be based on channel estimates computed by a channel estimator. The soft decisions are then decoded and de-interleaved to recover the data and control signals that were originally transmitted by the base station 204 on the physical channel. The data and control signals are then provided to the one or more processors 232, which implements Layer-3 (L3) and Layer-2 (L2) functionality.

In the downlink, the one or more processors 232 provides demultiplexing between transport and logical channels, packet reassembly, deciphering, header decompression, and control signal processing to recover IP packets from the core network. The one or more processors 232 are also responsible for error detection.

Similar to the functionality described in connection with the downlink transmission by the base station 204, the one or more processors 232 provides RRC layer functionality associated with system information (e.g., MIB, SIBs) acquisition, RRC connections, and measurement reporting; PDCP layer functionality associated with header compression/decompression, and security (ciphering, deciphering, integrity protection, integrity verification); RLC layer functionality associated with the transfer of upper layer PDUs, error correction through ARQ, concatenation, segmentation, and reassembly of RLC SDUs, re-segmentation of RLC data PDUs, and reordering of RLC data PDUs; and MAC layer functionality associated with mapping between logical channels and transport channels, multiplexing of MAC SDUs onto transport blocks (TBs), demultiplexing of MAC SDUs from TBs, scheduling information reporting, error correction through hybrid automatic repeat request (HARQ), priority handling, and logical channel prioritization.

Channel estimates derived by the channel estimator from a reference signal or feedback transmitted by the base station 204 may be used by the transmitter of the WWAN transceiver 210 to select the appropriate coding and modulation schemes, and to facilitate spatial processing. The spatial streams generated by the transmitter of the WWAN transceiver 210 may be provided to different antenna(s) 216. The transmitter of the WWAN transceiver 210 may modulate an RF carrier with a respective spatial stream for transmission.

The uplink transmission is processed at the base station 204 in a manner similar to that described in connection with the receiver function at the UE 202. The receiver of the WWAN transceiver 250 receives a signal through its respective antenna(s) 256. The receiver of the WWAN transceiver 250 recovers information modulated onto an RF carrier and provides the information to the one or more processors 284.

In the uplink, the one or more processors 284 provides demultiplexing between transport and logical channels, packet reassembly, deciphering, header decompression, control signal processing to recover IP packets from the UE 202. IP packets from the one or more processors 284 may be provided to the core network. The one or more processors 284 are also responsible for error detection.

For convenience, the UE 202, the base station 204, and/or the network entity 206 are shown in FIGS. 2A, 2B, and 2C as including various components that may be configured according to the various examples described herein. It will be appreciated, however, that the illustrated components may have different functionality in different designs. In particular, various components in FIGS. 2A to 2C are optional in alternative configurations and the various aspects include configurations that may vary due to design choice, costs, use of the device, or other considerations. For example, in case of FIG. 2A, a particular implementation of UE 202 may omit the WWAN transceiver(s) 210 (e.g., a wearable device or tablet computer or PC or laptop may have Wi-Fi and/or Bluetooth capability without cellular capability), or may omit the short-range wireless transceiver(s) 220 (e.g., cellular-only, etc.), or may omit the satellite signal receiver 230, and so on. In another example, in case of FIG. 2B, a particular implementation of the base station 204 may omit the WWAN transceiver(s) 250 (e.g., a Wi-Fi “hotspot” access point without cellular capability), or may omit the short-range wireless transceiver(s) 260 (e.g., cellular-only, etc.), or may omit the satellite signal receiver 270, and so on. For brevity, illustration of the various alternative configurations is not provided herein, but would be readily understandable to one skilled in the art.

The various components of the UE 202, the base station 204, and the network entity 206 may be communicatively coupled to each other over data buses 234, 282, and 292, respectively. In an aspect, the data buses 234, 282, and 292 may form, or be part of, a communication interface of the UE 202, the base station 204, and the network entity 206, respectively. For example, where different logical entities are embodied in the same device (e.g., gNB and location server functionality incorporated into the same base station 204), the data buses 234, 282, and 292 may provide communication between them.

The components of FIGS. 2A, 2B, and 2C may be implemented in various ways. In some implementations, the components of FIGS. 2A, 2B, and 2C may be implemented in one or more circuits such as, for example, one or more processors and/or one or more ASICs (which may include one or more processors). Here, each circuit may use and/or incorporate at least one memory component for storing information or executable code used by the circuit to provide this functionality. For example, some or all of the functionality represented by blocks 210 to 246 may be implemented by processor and memory component(s) of the UE 202 (e.g., by execution of appropriate code and/or by appropriate configuration of processor components). Similarly, some or all of the functionality represented by blocks 250 to 288 may be implemented by processor and memory component(s) of the base station 204 (e.g., by execution of appropriate code and/or by appropriate configuration of processor components). Also, some or all of the functionality represented by blocks 290 to 298 may be implemented by processor and memory component(s) of the network entity 206 (e.g., by execution of appropriate code and/or by appropriate configuration of processor components). For simplicity, various operations, acts, and/or functions are described herein as being performed “by a UE,” “by a base station,” “by a network entity,” etc. However, as will be appreciated, such operations, acts, and/or functions may actually be performed by specific components or combinations of components of the UE 202, base station 204, network entity 206, etc., such as the processors 232, 284, 294, the transceivers 210, 220, 250, and 260, the memories 240, 286, and 296, the power supplies 222, 262, and 297, the measurement correction component 242, 288, and 298, etc.

In some designs, the network entity 206 may be implemented as a core network component. In other designs, the network entity 206 may be distinct from a network operator or operation of the cellular network infrastructure. For example, the network entity 206 may be a component of a private network that may be configured to communicate with the UE 202 via the base station 204 or independently from the base station 204 (e.g., over a non-cellular communication link, such as WiFi).

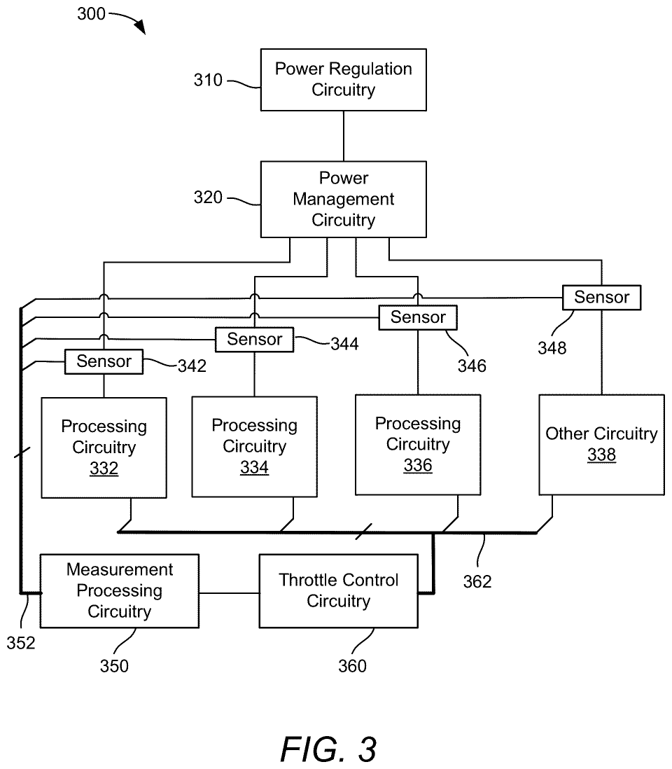

FIG. 3 is a functional block diagram illustrating a power management system in a computing device 300, according to aspects of the disclosure. In some aspects, the computing device 300 may correspond to the UE 202, the base station 204, and/or the network entity 206 are shown in FIGS. 2A, 2B, and 2C

The power management system of the computing device 300 may include power regulation circuitry 310 and power management circuitry 320. The power regulation circuitry 310 can receive electrical energy from an external power source and/or an internal power source and convert the electrical energy to regulated voltage sources and/or current sources. The power management circuitry 320 can distribute the regulated voltage sources and/or current sources from the power regulation circuitry 310 to various power regions or domains in the computing device 300, such as processing circuitry 332, processing circuitry 334, processing circuitry 336, and/or other circuitry 338.

In some aspects, the external power source is disposed outside the computing device 300 and may include an alternating current (AC) or a direct current (DC) power grid served by an electricity company, a locally installed, off-grid energy system, a power adapter coupled to the power grid or the off-grid energy system, or a battery, or a combination thereof. In some aspects, the external power source can provide the electrical energy to the computing device 300 via a conductive connection or an inductive power transmission. In some aspects, the internal power source is disposed on or inside the computing device 300 and may include a battery, a supercapacitor, a solar panel, a piezoelectric energy harvester, a kinetic energy harvester, or a combination thereof.

In some aspects, the power regulation circuitry 310 and the power management circuitry 320 may correspond to the power supplies 222, 262, and 297 in FIGS. 2A-2C. In some aspects, the processing circuitry 332, the processing circuitry 334, and the processing circuitry 336 may correspond to different circuit blocks in a processor core or different processor cores of processor(s) 232, 284, and 294 in FIGS. 2A-2C. In some aspects, the other circuitry 338 may correspond to a portion or all of components in the UE 202, the base station 204, and/or the network entity 206 other than the processor(s) 232, 284, and 294. For example, the other circuitry 338 may include a portion or an entirety of one or more of the transceiver 210, 220, 250, 260, 280, or 290, the satellite signal receiver 230 or 270, the memory 240, 286, or 296, or even the power supplies 222, 262, or 297.

The power management system of the computing device 300 may further include sensors 342, 344, 346, and 348. The sensors 342, 344, 346, and 348 can be configured to measure the power consumption levels of the processing circuitry 332, the processing circuitry 334, the processing circuitry 336, and the other circuitry 338, respectively. In some aspects, the sensors 342, 344, 346, and 348 can be current sensors configured to measure the respective current levels of circuitry 332, 334, 336, and 338. In some aspects, the sensors 342, 344, 346, and 348 can be voltage sensors configured to measure the respective voltage levels of circuitry 332, 334, 336, and 338. In some aspects, the sensors 342, 344, 346, and 348 may correspond to sensors 212, 252, and 295 in FIGS. 2A-2C.

Other types of sensors (not shown) may be disposed to measure the temperature of circuitry 332, 334, 336, or 338, the power regulation circuitry 310, the power management circuitry 320, or the computing device 300.

The power management system of the computing device 300 may include measurement processing circuitry 350 and throttle control circuitry 360. The measurement processing circuitry 350 can receive measured values from the sensors 342, 344, 346, and 348 via signal lines 352 and apply corrections to the measured values in order to obtain the corrected values as the measured power consumption levels of the circuitry 332, 334, 336, and 338 with requisite fidelity and accuracy. The throttle control circuitry 360 can obtain the measured power consumption levels from the measurement processing circuitry 350, compare the measured power consumption levels against one or more thresholds based on respective power budget(s), and determine the throttle amounts for the circuitry 332, 334, 336, and 338. The throttle control circuitry 360 can transmit the determined throttle amounts and/or control signals corresponding to the determined throttle amounts to the circuitry 332, 334, 336, and 338 via signal lines 362.

In some aspects, each of the circuitry 332, 334, 336, and 338 may include a corresponding throttle circuitry that is configured to throttle the performance of the circuitry 332, 334, 336, and 338 in order to keep the power consumption of individual circuitry within the respective power budgets. In some aspects, the throttle circuitry can use micro-architecture hardware techniques to throttle the performance by stalling a clock, throttling instructions, adjusting a clock frequency, any suitable throttling approaches, or a combination thereof. Accordingly, each one of the circuitry 332, 334, 336, and 338 may operate at the enhanced performance when its power consumption is within a predetermined power budget, and may mitigate the risk of violating the power budget by throttling its performance. In some aspects, the sensors 342, 344, 346, and 348 may be current sensors, and the throttle control circuitry 360 may be configured to detect current rate-of-change (di/dt) events based on sensor outputs and achieve corresponding power throttling (e.g., performance reduction to avoid violation of the power budget).

In some aspects, the measurement processing circuitry 350 may correspond to the measurement correction component 242, 288, and 298 in FIGS. 2A-2C. In some aspects, the throttle control circuitry 360 may be part of the power supplies 222, 262, and 297 in FIGS. 2A-2C. In some aspects, the throttle control circuitry 360 may be implemented as throttle control components disposed in the respective circuitry 332, 334, 336, and 338 it controls, or disposed outside the respective circuitry 332, 334, 336, and 338, or a combination thereof.

For example, current sensing can be used in peak power management in mobile devices under stringent end-to-end timing requirements. In some aspects, transient current levels of a circuit block in a device can be measured and/or accumulated in the order of hundreds of nano-seconds. However, in some aspects, various measures to mitigate possible violation of the power budgets (e.g., by performance throttling) of the circuit block may be imposed in the order of microseconds. Also, several sources (e.g., sensitivity, minimum voltage drop, offset correction, calibration, dynamic range, or di/dt) may affect the accuracy of the current sensing results, which may result in over or under throttling and hence impacting performance or stability of the circuit block.

In some aspects, considering a tradeoff between stability and performance, a conservative mitigation configuration may be deployed in favor of stability at the cost of some performance impacts. For example, trends in integrated computational capabilities of various SoC offerings shows similar power network design challenges to provide peak performance while properly sizing the footprint to optimize bill-of-materials (BOM) cost.

In some aspects, possible approaches may include deploying an oversize power network for the SoC at the penalty of BOM cost in order to allow relaxed power budgets. In some aspects, possible approaches may include utilizing an active peak power management that may have the potential of performing targeted risk mitigation with improved BOM cost whilst providing system stability, but possibly at the cost of limiting the full performance potential of the SoC.

In some aspects, the measurement processing circuitry 350 can perform measurement correction on a measured value from a sensor based on empirical data from the sensor.

In some aspects, the measurement processing circuitry 350 can include a proportional-integral-derivative (PID) hardware or module that can process a measured value corresponding to a power consumption level at a current time point and one or more previously measured values to obtain a corrected value representing the power consumption level at the current time point. The measurement processing circuitry 350 can be configured based on a set of measurement processing coefficients for the measurement correction.

Moreover, in some aspects, the set of measurement processing coefficients may be determined based on machine learning techniques. In some aspects, empirical time aligned (e.g., aligned measured value from a sensor and a reference or ground truth value) data for various workloads with requisite fidelity can be fed into a machine learning (ML) model to extract key features (i.e., PID coefficients, or measurement processing coefficients for configuring the PID hardware or module) that can be used to configure the measurement processing circuitry 350 to reduce dynamic errors of the measured power consumption levels in real-time.

Machine learning may be used to generate models that may be used to facilitate various aspects associated with processing of data. One specific application of machine learning relates to generation and/or update of measurement processing coefficients for configuring the measurement processing circuitry (e.g., circuitry including a PID hardware or module) as described with reference to FIG. 3. Another possible application of machine learning relates to generation of measurement models for processing of reference signals for positioning (e.g., positioning reference signal (PRS)), such as feature extraction, reporting of reference signal measurements (e.g., selecting which extracted features to report), and so on.

Machine learning models are generally categorized as either supervised or unsupervised. A supervised model may further be sub-categorized as either a regression or classification model. Supervised learning involves learning a function that maps an input to an output based on example input-output pairs. For example, given a training dataset with two variables of age (input) and height (output), a supervised learning model could be generated to predict the height of a person based on their age. In regression models, the output is continuous. One example of a regression model is a linear regression, which simply attempts to find a line that best fits the data. Extensions of linear regression include multiple linear regression (e.g., finding a plane of best fit) and polynomial regression (e.g., finding a curve of best fit).

Another example of a machine learning model is a decision tree model. In a decision tree model, a tree structure is defined with a plurality of nodes. Decisions are used to move from a root node at the top of the decision tree to a leaf node at the bottom of the decision tree (i.e., a node with no further child nodes). Generally, a higher number of nodes in the decision tree model is correlated with higher decision accuracy.

Another example of a machine learning model is a decision forest. Random forests are an ensemble learning technique that builds off of decision trees. Random forests involve creating multiple decision trees using bootstrapped datasets of the original data and randomly selecting a subset of variables at each step of the decision tree. The model then selects the mode of all of the predictions of each decision tree. By relying on a “majority wins” model, the risk of error from an individual tree is reduced.

Another example of a machine learning model is a neural network (NN). A neural network is essentially a network of mathematical equations. Neural networks accept one or more input variables, and by going through a network of equations, result in one or more output variables. Put another way, a neural network takes in a vector of inputs and returns a vector of outputs.

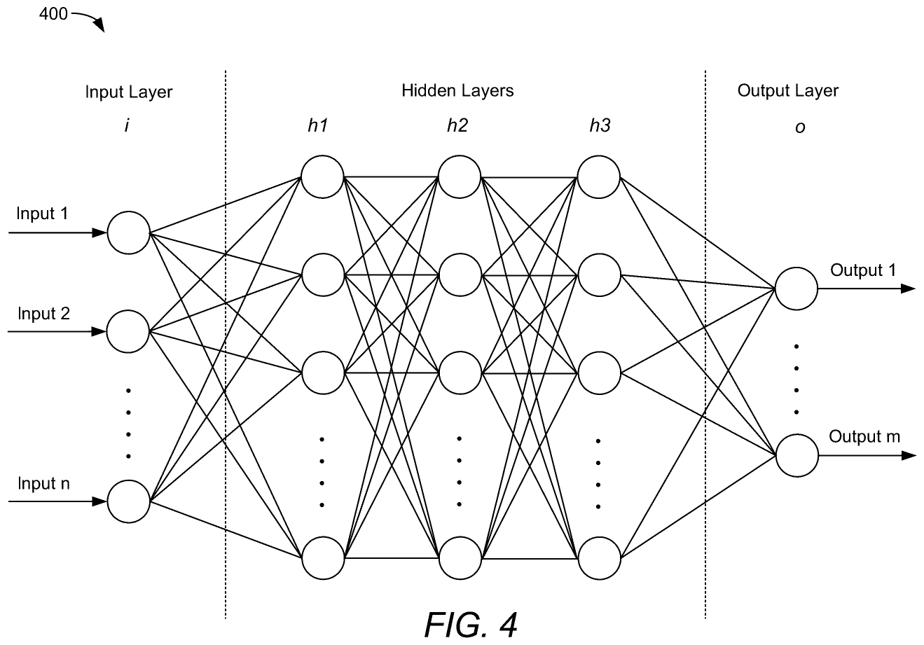

FIG. 4 illustrates an example neural network 400, according to aspects of the disclosure. The neural network 400 includes an input layer ‘i’ that receives ‘n’ (one or more) inputs (illustrated as “Input 1,” “Input 2,” and “Input n”), one or more hidden layers (illustrated as hidden layers ‘h1,’ ‘h2,’ and ‘h3’) for processing the inputs from the input layer, and an output layer ‘o’ that provides ‘m’ (one or more) outputs (labeled “Output 1” and “Output m”). The number of inputs ‘n,’ hidden layers ‘h,’ and outputs ‘m’ may be the same or different. In some designs, the hidden layers ‘h’ may include linear function(s) and/or activation function(s) that the nodes (illustrated as circles) of each successive hidden layer process from the nodes of the previous hidden layer.

In classification models, the output is discrete. One example of a classification model is logistic regression. Logistic regression is similar to linear regression but is used to model the probability of a finite number of outcomes, typically two. In essence, a logistic equation is created in such a way that the output values can only be between ‘0’ and ‘1.’ Another example of a classification model is a support vector machine. For example, for two classes of data, a support vector machine will find a hyperplane or a boundary between the two classes of data that maximizes the margin between the two classes. There are many planes that can separate the two classes, but only one plane can maximize the margin or distance between the classes. Another example of a classification model is Naïve Bayes, which is based on Bayes Theorem. Other examples of classification models include decision tree, random forest, and neural network, similar to the examples described above except that the output is discrete rather than continuous.

Unlike supervised learning, unsupervised learning is used to draw inferences and find patterns from input data without references to labeled outcomes. Two examples of unsupervised learning models include clustering and dimensionality reduction.

Clustering is an unsupervised technique that involves the grouping, or clustering, of data points. Clustering is frequently used for customer segmentation, fraud detection, and document classification. Common clustering techniques include k-means clustering, hierarchical clustering, mean shift clustering, and density-based clustering. Dimensionality reduction is the process of reducing the number of random variables under consideration by obtaining a set of principal variables. In simpler terms, dimensionality reduction is the process of reducing the dimension of a feature set (in even simpler terms, reducing the number of features). Most dimensionality reduction techniques can be categorized as either feature elimination or feature extraction. One example of dimensionality reduction is called principal component analysis (PCA). In the simplest sense, PCA involves project higher dimensional data (e.g., three dimensions) to a smaller space (e.g., two dimensions). This results in a lower dimension of data (e.g., two dimensions instead of three dimensions) while keeping all original variables in the model.

Regardless of which machine learning model is used, at a high-level, a machine learning module (e.g., implemented by a processing system, such as processors 232, 284, or 294) may be configured to iteratively analyze training input data (e.g., measurements of reference signals to/from various target UEs) and to associate this training input data with an output data set (e.g., a set of possible or likely candidate locations of the various target UEs), thereby enabling later determination of the same output data set when presented with similar input data (e.g., from other target UEs at the same or similar location).

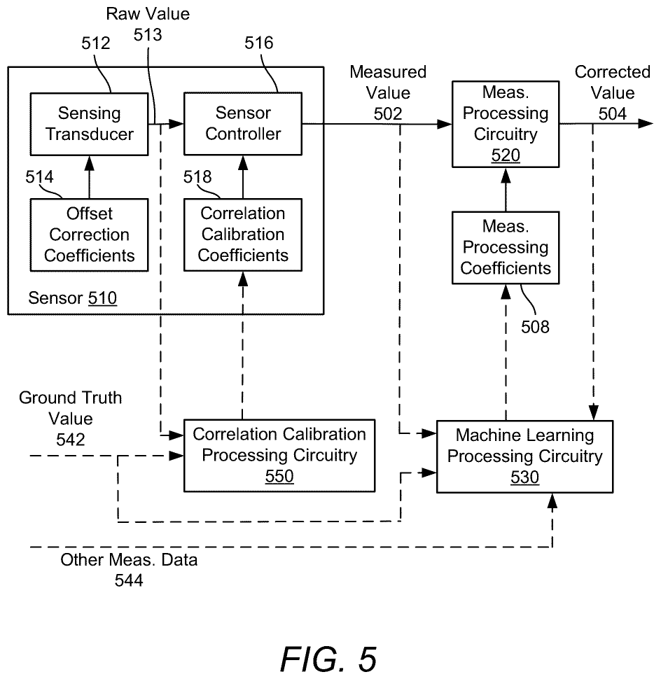

FIG. 5 is a diagram illustrating operations for obtaining a measured value 502, operations for obtaining a corrected value 504 based on a set of measurement processing coefficients 508 during a correction inference phase, and operations for determining the set of measurement processing coefficients 508 during a model training phase, according to aspects of the disclosure.

As shown in FIG. 5, a sensor 510 can measure a power consumption level (e.g., a current level or a voltage level) of a measured object (e.g., a circuit block in a device) and output a measured value 502 corresponding to the power consumption level of the measured object at a first time point (e.g., a current time point). Prior to obtaining the measured value 502, sensor 510 can measure and output one or more other measured values corresponding to one or more other power consumption levels of the measured object at one or more second time points (e.g., prior time points) earlier than the first time point. In some aspects, sensor 510 may correspond to sensors 212, 252, and 295 in FIGS. 2A-2C and/or sensors 342, 344, 346, and 348 and in FIG. 3.

In some aspects, measurement processing circuitry 520 can be configured based on the set of measurement processing coefficients 508. During the correction inference phase, measurement processing circuitry 520, as configured based on the set of measurement processing coefficients 508, can obtain the measured value 502 and the one or more other measured values from sensor 510 and determine the corrected value 504 based on the measured value 502 and the one or more other measured values. Moreover, during the model training phase, machine learning processing circuitry 530 can receive the measured value 502 and the one or more other measured values from sensor 510, the corrected value 504, the corresponding ground truth value 542, and/or other measurement data 544, and train a machine learning model for updating the set of measurement processing coefficients 508. In some aspects, measurement processing circuitry 520 may correspond to measurement correction component 242, 288, and 298 in FIGS. 2A-2C and/or measurement processing circuitry 350 in FIG. 3.

In some aspects, measured values from the sensors and the ground truth values can be of different sampling rates with different time sources. Accordingly, in some aspects, the ground truth values may be firstly resample, and the data streams of the measured values and the ground truth values may be time-aligned using hardware markers and/or Fast Fourier Transform (FFT) cross correlation techniques.

The sensor 510 may include a sensing transducer 512 that can convert the power consumption level of the measured object into a voltage signal or a current signal to be picked up as a raw value corresponding to the power consumption level of the measured object. In some aspects, the sensing transducer 512 may include transistors, resistive devices, and/or other components that are configured as one or more of a current mirror, an amplifier, and/or an operational amplifier. In some aspects, the sensing transducer 512 may further includes an Analog-to-Digital Converter (ADC) to convert the raw value from an analog form into a digital form.

In some aspects, process shifts during the manufacturing process and mismatches of the components of the sensing transducer 512 may introduce an error to the sensed voltage signal or current signal. In some aspects, such error may be at least partially correctable by applying an offset correction to the sensing transducer 512. Therefore, in some aspects, the sensing transducer 512 may be configured based on a set of offset correction coefficients 514 at power-up of the sensor 510 in order to imposing an offset correction to the raw value 513. In some aspects, the set of offset correction coefficients 514 may include information regarding selectively turning on or off certain electrical paths in the sensing transducer 512 in order to compensate for the offset, or an offset value to be incorporated into the raw value. In some aspects, the set of offset correct coefficients 514 may be determined during a product testing stage as part of the manufacturing process of the sensor 510 or a computing device that includes the sensor 510. In some aspects, the set of offset correction coefficients 514 can be implemented as a programmable resistor or transistor array, a programmable fuse array, stored in a programmable read-only memory inside the sensor 510, stored in a reprogrammable memory inside the sensor 510, or stored in a memory outside the sensor 510.

The sensor 510 may include a sensor controller 516 that is configured to control the operation of sensor 510 and to adjust the raw value 513 to become the measured value 502 based on a set of correlation calibration coefficients 518. In some aspects, working conditions of the sensor 510 (e.g., a temperature, or characteristic shifts of the components of the sensing transducer 512 over time) or hardware design or bandwidth limitations of the sensor 510 may introduce an error to the raw value that may be at least partially correctable by referring to a correlation between the raw values and a corresponding ground truth value 542. In some aspects, such correlation information may be determined by correlation calibration processing circuitry 550 offline (e.g., during the model training phase or a dedicated correlation calibration phase) based on the ground truth value 542 and the raw value 513. Based on the correlation information, correlation calibration processing circuitry 550 can determine and provide a set of correlation calibration coefficients 518 to the sensor controller 516, where the sensor controller 516 can adjust the raw value 513 based on the set of correlation calibration coefficients 518 to obtain a measured value as the output value of the sensor 510.

In some aspects, the correlation calibration processing circuitry 550 can be part of an external instrument different from the computing device that includes the sensor 510. In some aspects, the correlation calibration processing circuitry 550 can be implemented as part of the measurement correction component 242, 288, and 298. In some aspects, the set of correlation calibration coefficients 518 can be stored in a programmable read-only memory inside the sensor 510, stored in a reprogrammable memory inside the sensor 510, or stored in a memory outside the sensor 510.

Moreover, in some aspects, the ground truth value 542 can be provided by an external instrument different from the computing device that includes the sensor 510. In some aspects, the ground truth value 542 can be one of multiple predetermined values stored in the computing device that correspond to respective predetermined testing operations of the measured object.

In some aspects, the process shifts and mismatches of the components of the sensing transducer 512 and the working conditions or hardware design or bandwidth limitations of the sensor 510 may introduce an error that may not be correctable by sensing transducer 512 based on the set of offset correction coefficients 514 nor by the sensor controller 516 based on the set of correlation calibration coefficients 518. In some aspects, measurement processing circuitry 520 as configured based on the set of measurement processing coefficients 508 can be used to correct the errors that may be non-correctable by the sensing transducer 512 and/or the sensor controller 516. In some aspects, measurement processing circuitry 520 can include PID hardware or module that can process the measured value 502 and one or more previously measured values to obtain the corrected value 504 in order to correct the errors that may be non-correctable by the sensing transducer 512 and/or the sensor controller 516. Accordingly, measurement processing circuitry 520 can improve the sensing accuracy of the measured power consumption level and hence enhance the accuracy of detecting and mitigating potential power budget violations.

In some aspects, during the correction inference phase, measurement processing circuitry 520 can determine a proportional term based on the measured value 502, determine an integral term based on the measured value 502 and the one or more other measured values, and determine a differential term based on the measured value 502 and at least one of the one or more second measured values. In some aspects, measurement processing circuitry 520 can determine the corrected value 504 based on a weighted combination of the proportional term, the integral term, and the differential term.

In some aspects, during the correction inference phase, the weighted combination of the proportional term, the integral term, and the differential term can be calculated based on an expression of Oᵢ=I_{Pi}*W_{P}+I_{Ii}*W_{I}+I_{Di}*W_{D}+W_{B}, where Oᵢ represents the corrected value corresponding to the time point of the current measurement, I_{Pi} represents the proportional term, I_{Ii} represents the integral term, I_{Di} represents the differential term, W_{P} represents a first weight for the proportional term, W_{I} represents a second weight for the integral term, W_{D} represents a third weight for the differential term, and W_{B} represents a correction offset weight (e.g., a static bias offset or a constant correction offset that can be termed as a bias weight). In some aspects, the measured value 502 at a current time point T is denoted as S_{T}, the one or more other measured values include a measured value S_{T-1} corresponding to a time point T−1, a measured value S_{T-2} corresponding to a time point T−2, and a measured value S_{T-3} corresponding to a time point T−3, where T, T−1, T−2, and T−3 represent four consecutive time points according to a sampling period of the sensor. In some aspects, the proportional term can be based on S_{T}; the integral term can be based on an average of S_{T}, S_{T-1}, S_{T-2}, and S_{T-3}, and the differential term can be based on S_{T}−S_{T-1}. In some aspects, the weights W_{P}, W_{I}, and W_{D} may be based on the set of measurement processing coefficients.

In some aspects, during the model training phase, machine learning processing circuitry 530 can obtain the measured value 502 of a measured object corresponding to a current power consumption level at a current time point, one or more other measured values of the measured object corresponding to one or more other power consumption levels of the measured object at one or more earlier time points, and/or a corrected value that is determined based on the measured value and the one or more other measured values. In some aspects, machine learning processing circuitry 530 can be implemented by processor(s) 232, 284, and 294 in FIGS. 2A-2C and/or processing circuitry 332, 334, and 336 in FIG. 3.

Machine learning processing circuitry 530 can train a machine learning model for determining an updated set of measurement processing coefficients of the measurement processing circuitry 520. In some aspects, the training the machine learning model can be performed based on training input data and training reference data, where the training input data can include the measured value 502, the one or more other measured values, or the corrected value 504, or a combination thereof; and the training reference data can include a ground truth value 542 of the current power consumption level. In some aspects, the training input data can further include measurement data 544 from one or more other sensors. For example, when the sensor 510 sense a current level of the measured object the other measurement data may include process, voltage, and temperature (PVT) related measurements. In some aspects, the machine learning model cane be trained by machine learning processing circuitry 530 offline (e.g., during the model training phase or a period of time where the corresponding ground truth value is obtainable from an external instrument).

In some aspects, during the model training phase, measurement processing circuitry 520 can be configured based on the updated set of measurement processing coefficients after the machine learning model is trained based on the training input data and the training reference data. Measurement processing circuitry 520 that is configured based on the updated set of measurement processing coefficients can be used to correct the errors for measured values from current sensor 510 during a subsequent, correction inference phase.

During the model training phase, machine learning processing circuitry 530 can train a machine learning model that is based on a linear regression model of a weighted combination of the proportional term, the integral term, and the differential term, such as based on an expression of Rᵢ=Iᵢ*W_{P}+I_{Ii}*W_{I}+I_{Di}*W_{D}+W_{B}+Eᵢ, where Rᵢ represents the ground truth value corresponding to the current time point, I_{Pi} represents the proportional term, I_{Ii} represents the integral term, I_{Di} represents the differential term, W_{P} represents a first weight for the proportional term, W_{I} represents a second weight for the integral term, W_{D} represents a third weight for the differential term, W_{B} represents a correction offset weight (e.g., a static bias offset or a constant correction offset that can be termed as a bias weight), and Eᵢ represents a constant bias error correction offset to be determined through the training process. In some aspects, the measured value 502 at a current time point T is denoted as S_{T}, the one or more other measured values include a measured value S_{T-1} corresponding to a time point T−1, a measured value S_{T-2} corresponding to a time point T−2, and a measured value S_{T-3} corresponding to a time point T−3, where T, T−1, T−2, and T−3 represent four consecutive time points according to a sampling period of the sensor. In some aspects, the proportional term can be based on S_{T}; the integral term can be based on an average of S_{T}, S_{T-1}, S_{T-2}, and S_{T-3}, and the differential term can be based on S_{T}−S_{T-1}.

In some aspects, the training input data is based on the measured value, the one or more other measured values, the corrected value, a value derived from the measured values (e.g., the P, I, D term features, including the proportional term, the integral term, and/or the differential term extracted from processed measured values), or a combination thereof.

In some aspects, the training input data may include I_{Pi}, I_{Ii}, and I_{Di} from a plurality of time points. For example, the training input data Ii can include [I_{Pi}, I_{Ii}, I_{Di}]=[{S_{T}, mean (S_{T}, S_{T-1}, S_{T-2}, S_{T-3}), (S_{T}−S_{T-1})}, {S_{T+1}, mean (S_{T+1}, S_{T}, S_{T-1}, S_{T-2}), (S_{T+1}−S_{T})}, {S_{T+2}, mean (S_{T+2}, S_{T+1}, S_{T}, S_{T-1}), (S_{T+2}−S_{T+1})}, {S_{T+3}, mean (S_{T+3}, S_{T+2}, S_{T+1}, S_{T}), (S_{T+3}−S_{T+2})}, . . . ] based on measure values at time points T−3, T−2, T−1, T, T+1, T+2, T+3, . . . . In some aspects, the corresponding training reference data may include G_{T}, G_{T+1}, G_{T+2}, G_{T+3} . . . , where G_{T}, G_{T+1}, G_{T+2}, G_{T+3} represent the ground truth values corresponding to power consumption levels at time points T, T+1, T+2, T+3, respectively. In some aspects, the ground truth values can be measured and provided by an external instrument outside the computing device that includes the sensor 510.

In some aspects, the set of measurement processing coefficients 508 can be implemented as a programmable resistor or transistor array for configuring measurement processing circuitry 520, a programmable fuse array for configuring measurement processing circuitry 520, stored in a programmable read-only memory, stored in a reprogrammable memory, or stored in a memory outside the sensor 510. In some aspects, once a set of measurement processing coefficients is determined by machine learning processing circuitry 530, the set of measurement processing coefficients can be programmed in the hardware in the measurement processing circuitry 520 as static settings or semi-static settings for an entirety or a significant portion of the life of the computing device.

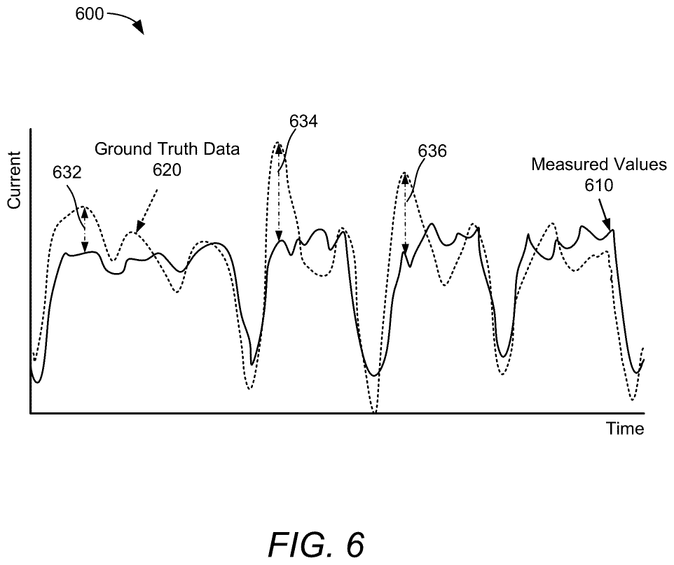

FIG. 6 is a graph 600 illustrating a curve representing measured values 610 output by sensor 510 in FIG. 5 and a curve representing ground truth values 620 measured and provide by an external instrument, according to aspects of the disclosure. In this example, the measured values 610 may correspond to current consumption levels of the measured object, such as a circuit block of a computing device. The external instrument is different from the computing device. Thus, the horizontal axis is in units of time (e.g., microseconds) and the vertical axis is in units of current level (e.g., micro-amperes). In some aspects, the measured values 610 and the ground truth values 620 depicted in graph 600 have been resampled and time-aligned, using hardware markers and Fast Fourier Transform (FFT) cross-correlation techniques.

In some aspects, the measured values 610 represents the measurement results that have been corrected and calibrated by sensing transducer 512 based on the set of offset correction coefficients 514 and by sensor controller 516 based on the set of correlation calibration coefficients 518. However, at occasions 632, 634, and 636, the measured values may still significantly underestimate the corresponding current consumption levels. Such underestimation may correspond to errors that are non-correctable by the sensing transducer 512 and/or the sensor controller 516, and may be dynamic in nature. In some aspects, the non-correctable, dynamic errors described above may result in increased likelihood of violation of the corresponding power budget.

In some aspects, the measurement processing circuitry 520 (e.g., including PID hardware or module) configured based on the set of measurement processing coefficients 508 can determine corrected values to correct the non-correctable, dynamic errors described above (e.g., the discrepancies at occasions 632, 634, and 636). In some aspects, the set of measurement processing coefficients 508 (e.g., PID coefficients) can be determined using machine learning techniques with time-aligned sensor and ground truth data.

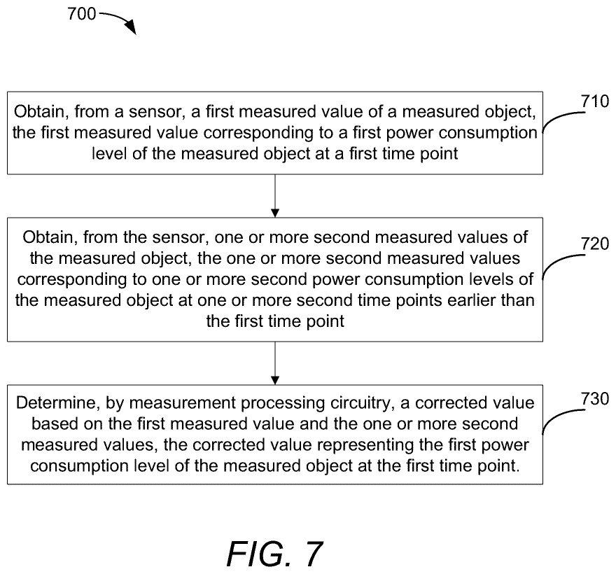

FIG. 7 illustrates an example method 700 of measurement correction during at least a correction inference phase, according to aspects of the disclosure. In some aspects, method 700 may be performed by a UE (which may correspond to any of the UEs described herein), a base station (which may correspond to any of the base stations described herein), and a network entity (which may correspond to or embody any of the network functions described herein. In some aspects, method 700 may correspond to the operations performed by at least sensors 212, 252, and 295 and measurement correction component 298 in FIGS. 2A-2C, by sensors 342, 344, 346, and 348 and measurement processing circuitry 350 in FIG. 3, and/or by sensor 510 and measurement processing circuitry 520 in FIG. 5, any or all of which may be considered means for performing one or more of the following operations of method 700.

At 710, measurement processing circuitry (e.g., measurement processing circuitry 350 or 510) obtains, from a sensor (e.g., sensors 342, 344, 346, and 348 or sensor 510), a first measured value of a measured object, the first measured value corresponding to a first power consumption level of the measured object at a first time point (e.g. a current time point).

At 720, the measurement processing circuitry obtains, from the sensor, one or more second measured values of the measured object, the one or more second measured values corresponding to one or more second power consumption levels of the measured object at one or more second time points earlier than the first time point (e.g. earlier time points).

In some aspects, the measured object is a circuit block (e.g., an entirety or a portion of the processors 232, 284, and 294, an entirety or a portion of the transceivers 210, 220, 250, 260, 280, and 290, an entirety or a portion of the receivers 230 and 270, and/or any circuitry components in FIGS. 2A-2C). In some aspects, the first power consumption level and the one or more second power consumption levels correspond to current levels of the circuit block at various measurement time points.

At 730, the measurement processing circuitry determines a corrected value based on the first measured value and the one or more second measured values, the corrected value representing the first power consumption level of the measured object at the first time point.

In some aspects, the measurement processing circuitry can obtain, from machine learning processing circuitry, a set of measurement processing coefficients. In some aspects, the measurement processing circuitry can be configured based on the set of measurement processing coefficients. As such, the corrected value can be determined by processing the first measured value and the one or more second measured values based on the set of measurement processing coefficients.

In some aspects, the measurement processing circuitry can include PID hardware or module. In some aspects, the measurement processing circuitry can determine a proportional term based on the first measured value, determine an integral term based on the first measured value and the one or more second measured values, and determine a differential term based on the first measured value and at least one of the one or more second measured values. In some aspects, the measurement processing circuitry can determine the corrected value based on a weighted combination of the proportional term, the integral term, and the differential term. In some aspects, during a correction inference phase, the weighted combination of the proportional term, the integral term, and the differential term can be calculated based on an expression of Oᵢ=I_{Pi}*W_{P}+I_{Ii}*W_{I}+I_{Di}*W_{D}+W_{B}+Eᵢ, as illustrated with reference to FIG. 5.

As will be appreciated, a technical advantage of the method 700 is to address the non-correctable, dynamic errors described above (e.g., the errors that are non-correctable by the sensing transducer 512 and/or the sensor controller 516). Accordingly, using the determined corrected value based on coefficients derived by machine learning techniques as the measured power consumption level can improve the sensing accuracy, and hence enhance the accuracy of detecting and mitigating potential power budget violations. Moreover, the increase in sensor accuracy will help to tune the control settings optimally to uplift possible performance while keeping the power within the allocated power budget.

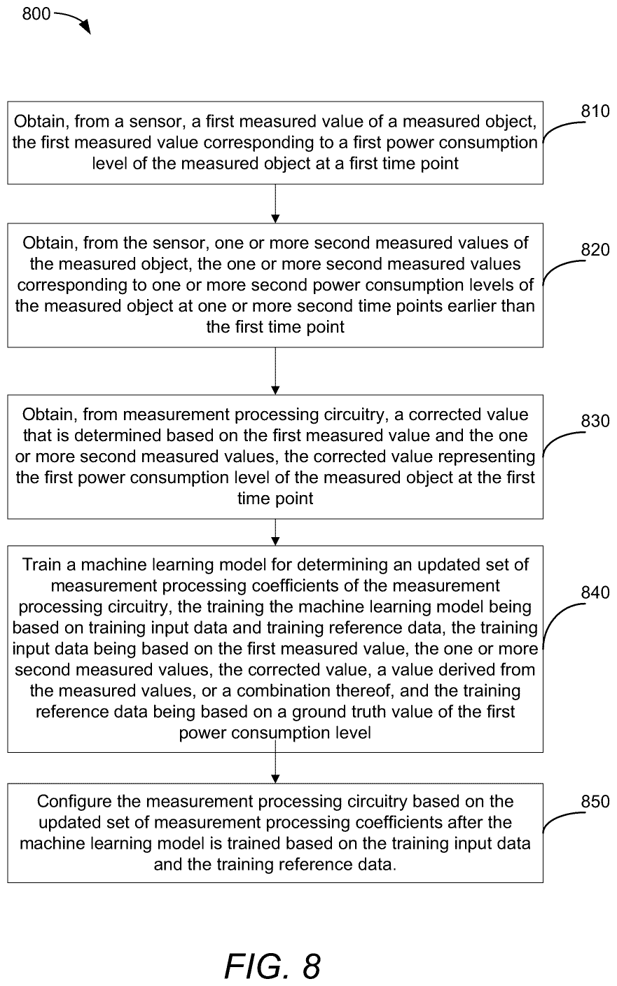

FIG. 8 illustrates an example method 800 of measurement correction during at least a model training phase, according to aspects of the disclosure. In some aspects, method 800 may be performed by a UE (which may correspond to any of the UEs described herein), a base station (which may correspond to any of the base stations described herein), and a network entity (which may correspond to or embody any of the network functions described herein. In some aspects, method 800 may correspond to the operations performed by at least sensors 212, 252, and 295 and processors 232, 284, and 294 in FIGS. 2A-2C, by sensors 342, 344, 346, and 348 and processing circuitry 332, 334, and 336 in FIG. 3, and/or by sensor 510 and machine learning processing circuitry 550 in FIG. 5, any or all of which may be considered means for performing one or more of the following operations of method 800.

At 810, machine learning processing circuitry (e.g., processing circuitry 332, 334, and 336 or machine learning processing circuitry 550) obtains, from a sensor (e.g., sensors 342, 344, 346, and 348 or sensor 510), a first measured value of a measured object, the first measured value corresponding to a first power consumption level of the measured object at a first time point (e.g. a current time point).

At 820, the machine learning processing circuitry obtains, from the sensor, one or more second measured values of the measured object, the one or more second measured values corresponding to one or more second power consumption levels of the measured object at one or more second time points earlier than the first time point (e.g. earlier time points).

In some aspects, the measured object is a circuit block (e.g., an entirety or a portion of the processors 232, 284, and 294, an entirety or a portion of the transceivers 210, 220, 250, 260, 280, and 290, an entirety or a portion of the receivers 230 and 270, and/or any circuitry components in FIGS. 2A-2C). In some aspects, the first power consumption level and the one or more second power consumption levels correspond to current levels of the circuit block at various measurement time points.

At 830, the machine learning processing circuitry obtains, from measurement processing circuitry, a corrected value that is determined based on the first measured value and the one or more second measured values, the corrected value representing the first power consumption level of the measured object at the first time point (e.g. current time point).

At 840, the machine learning processing circuitry trains a machine learning model for determining an updated set of measurement processing coefficients of the measurement processing circuitry. In some aspects, the training the machine learning model is based on training input data and training reference data, the training input data being based on the first measured value, the one or more second measured values, the corrected value, a value derived from the measured values (e.g., the P, I, D term features, including the proportional term, the integral term, and/or the differential term extracted from processed measured values), or a combination thereof, and the training reference data being based on a ground truth value of the first power consumption level at the first time point (e.g. current time point).

In some aspects, the machine learning processing circuitry can obtain measurement data from one or more other sensors, and the training input data can be further based on at least a portion of the measurement data.

In some aspects, the machine learning model trained by the machine learning processing circuitry can be based on a linear regression model of a weighted combination of a proportional term, an integral term, and a differential term, such as based on an expression of Rᵢ=I_{Pi}*W_{P}+I_{Ii}*W_{I}+I_{Di}*W_{D}+W_{B}+Eᵢ, as illustrated with reference to FIG. 5.

At 850, the machine learning processing circuitry configures the measurement processing circuitry based on the updated set of measurement processing coefficients after the machine learning model is trained based on the training input data and the training reference data.

In some aspects, the UE that is configured to perform the method 700 in FIG. 7 can be configured to perform the method 800 in FIG. 8. In some aspects, the UE can use the model trained according to the method 800 in the method 700. In some aspects, the UE can use the measured values obtained in the method 700 as training input data in the method 800.

As will be appreciated, a technical advantage of the method 800 is to address the non-correctable, dynamic errors described above (e.g., the errors that are non-correctable by the sensing transducer 512 and/or the sensor controller 516). The set of measurement processing coefficients for configuring the measurement proceeding circuitry can be updated based on machine learning techniques. Accordingly, the coefficients for determining the corrected value as the measured power consumption level can be timely and dynamically updated in order to improve the sensing accuracy, and hence enhance the accuracy of detecting and mitigating potential power budget violations. Moreover, the increase in sensor accuracy will help to tune the control settings optimally to uplift possible performance while keeping the power within the allocated power budget.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:

Clause 1. A method of measurement correction, comprising: obtaining, from a sensor, a first measured value of a measured object, the first measured value corresponding to a first power consumption level of the measured object at a first time point; obtaining, from the sensor, one or more second measured values of the measured object, the one or more second measured values corresponding to one or more second power consumption levels of the measured object at one or more second time points earlier than the first time point; and determining, by measurement processing circuitry, a corrected value based on the first measured value and the one or more second measured values, the corrected value representing the first power consumption level of the measured object at the first time point.

Clause 2. The method of clause 1, further comprising: obtaining, from machine learning processing circuitry, a set of measurement processing coefficients, wherein the determining the corrected value comprises processing the first measured value and the one or more second measured values based on the set of measurement processing coefficients.

Clause 3. The method of clause 2, further comprising: outputting, to the machine learning processing circuitry, the first measured value, the one or more second measured values, the corrected value, a value derived from the measured value, or a combination thereof, wherein the first measured value, the one or more second measured values, the corrected value, the value derived from the measured value, or a combination thereof enable the machine learning processing circuitry to train a machine learning model for determining an updated set of measurement processing coefficients of the measurement processing circuitry.

Clause 4. The method of any of clauses 1 to 3, wherein the determining the corrected value comprises: determining a proportional term based on the first measured value; determining an integral term based on the first measured value and the one or more second measured values; determining a differential term based on the first measured value and at least one of the one or more second measured values; and determining the corrected value based on a weighted combination of the proportional term, the integral term, and the differential term.

Clause 5. The method of clause 4, wherein the weighted combination of the proportional term, the integral term, and the differential term is calculated based on an expression of Oᵢ=I_{Pi}*W_{P}+I_{Ii}*W_{I}+I_{Di}*W_{D}+W_{B}, where: Oᵢ representing the corrected value corresponding to the first time point, I_{Pi} representing the proportional term, I_{Ii} representing the integral term, I_{Di} representing the differential term, W_{P} representing a first weight for the proportional term, W_{I} representing a second weight for the integral term, W_{D} representing a third weight for the differential term, and W_{B} represents a correction offset weight.

Clause 6. The method of any of clauses 4 to 5, wherein the first measured value at the first time point T is denoted as S_{T}, the one or more second measured values include a measured value S_{T-1} corresponding to a time point T−1, a measured value S_{T-2} corresponding to a time point T−2, and a measured value S_{T-3} corresponding to a time point T−3, T, T−1, T−2, and T−3 represent four consecutive time points according to a sampling period of the sensor, the proportional term is based on S_{T}, the integral term is based on an average of S_{T}, S_{T-1}, S_{T-2}, and S_{T-3}, and the differential term is based on S_{T}−S_{T-1}.

Clause 7. The method of any of clauses 1 to 6, wherein the obtaining the first measured value of the measured object comprises: obtaining, from a sensing transducer of the sensor, a raw value corresponding to the first power consumption level; and adjusting, by a sensor controller of the sensor, the raw value based on a set of calibration coefficients to obtain the first measured value.

Clause 8. The method of clause 7, further comprising: configuring the sensing transducer of the sensor based on a set of offset correction coefficients.

Clause 9. The method of any of clauses 1 to 8, wherein: the measured object is a circuit block, and the first power consumption level corresponds to a current level of the circuit block.

Clause 10. A method of measurement correction, comprising: obtaining, from a sensor, a first measured value of a measured object, the first measured value corresponding to a first power consumption level of the measured object at a first time point; obtaining, from the sensor, one or more second measured values of the measured object, the one or more second measured values corresponding to one or more second power consumption levels of the measured object at one or more second time points earlier than the first time point; obtaining, from measurement processing circuitry, a corrected value that is determined based on the first measured value and the one or more second measured values, the corrected value representing the first power consumption level of the measured object at the first time point; training a machine learning model for determining an updated set of measurement processing coefficients of the measurement processing circuitry, the training the machine learning model being based on training input data and training reference data, the training input data being based on the first measured value, the one or more second measured values, the corrected value, a value derived from the measured values, or a combination thereof, and the training reference data being based on a ground truth value of the first power consumption level; and configuring the measurement processing circuitry based on the updated set of measurement processing coefficients after the machine learning model is trained based on the training input data and the training reference data.

Clause 11. The method of clause 10, further comprising: obtaining measurement data from one or more other sensors, wherein the training input data is further based on at least a portion of the measurement data.

Clause 12. The method of any of clauses 10 to 11, wherein the machine learning model is arranged based on a weighted combination of a proportional term, an integral term, and a differential term, the proportional term is determined based on the first measured value, the integral term is determined based on the first measured value and the one or more second measured values, and the differential term is determined based on the first measured value and at least one of the one or more second measured values.

Clause 13. The method of clause 12, wherein the machine learning model is arranged based on an expression of Rᵢ=I_{Pi}*W_{P}+I_{Ii}*W_{I}+I_{Di}*W_{D}+W_{B}+Eᵢ, where: Rᵢ representing the ground truth value corresponding to the first time point, I_{Pi} representing the proportional term, I_{Ii} representing the integral term, I_{Di} representing the differential term, W_{P} representing a first weight for the proportional term, W_{I} representing a second weight for the integral term, W_{D} representing a third weight for the differential term, W_{B} representing a correction offset weight, and Eᵢ representing a constant bias error correction offset to be determined through the training the machine learning model.

Clause 14. The method of any of clauses 12 to 13, wherein the first measured value at the first time point T is denoted as S_{T}, the one or more second measured values include a measured value S_{T-1} corresponding to a time point T−1, a measured value S_{T-2} corresponding to a time point T−2, and a measured value S_{T-3} corresponding to a time point T−3, T, T−1, T−2, and T−3 represent four consecutive time points according to a sampling period of the sensor, the proportional term is based on S_{T}, the integral term is based on an average of S_{T}, S_{T-1}, S_{T-2}, and S_{T-3}, and the differential term is based on S_{T}−S_{T-1}.

Clause 15. The method of any of clauses 10 to 14, further comprising: obtaining, from a sensing transducer of the sensor, a raw value corresponding to the first power consumption level; and determining a set of calibration coefficients based on the raw value and the ground truth value of the first power consumption level, the set of calibration coefficients enabling a sensor controller of the sensor to adjust the raw value based on the set of calibration coefficients to obtain the first measured value.

Clause 16. The method of clause 15, further comprising: configuring the sensor controller of the sensor based on the updated set of calibration coefficients.

Clause 17. The method of any of clauses 10 to 16, wherein: the measured object is a circuit block, and the first power consumption level corresponds to a current level of the circuit block.

Clause 18. A computing device, comprising: a memory; and at least one processor communicatively coupled to the memory, the at least one processor configured to: obtain, from a sensor, a first measured value of a measured object, the first measured value corresponding to a first power consumption level of the measured object at a first time point; obtain, from the sensor, one or more second measured values of the measured object, the one or more second measured values corresponding to one or more second power consumption levels of the measured object at one or more second time points earlier than the first time point; and determine a corrected value based on the first measured value and the one or more second measured values, the corrected value representing the first power consumption level of the measured object at the first time point.

Clause 19. The computing device of clause 18, wherein the at least one processor is further configured to: obtain, from machine learning processing circuitry, a set of measurement processing coefficients, wherein the at least one processor configured to determine the corrected value is further configured to process the first measured value and the one or more second measured values based on the set of measurement processing coefficients.

Clause 20. The computing device of clause 19, wherein the at least one processor is further configured to: output, to the machine learning processing circuitry, the first measured value, the one or more second measured values, the corrected value, or a combination thereof, wherein the first measured value, the one or more second measured values, the corrected value, or a combination thereof enable the machine learning processing circuitry to train a machine learning model for determining an updated set of measurement processing coefficients.

Clause 21. The computing device of any of clauses 18 to 20, wherein the at least one processor configured to determine the corrected value is further configured to: determine a proportional term based on the first measured value; determine an integral term based on the first measured value and the one or more second measured values; determine a differential term based on the first measured value and at least one of the one or more second measured values; and determine the corrected value based on a weighted combination of the proportional term, the integral term, and the differential term.

Clause 22. The computing device of clause 21, wherein the weighted combination of the proportional term, the integral term, and the differential term is calculated based on an expression of Oᵢ=I_{Pi}*W_{P}+I_{Ii}*W_{I}+I_{Di}*W_{D}+W_{B}, where: Oᵢ representing the corrected value corresponding to the first time point, I_{Pi} representing the proportional term, I_{Ii} representing the integral term, I_{Di} representing the differential term, W_{P} representing a first weight for the proportional term, W_{I} representing a second weight for the integral term, W_{D} representing a third weight for the differential term, and W_{B} represents a correction offset weight.

Clause 23. The computing device of any of clauses 21 to 22, wherein the first measured value at the first time point T is denoted as S_{T}, the one or more second measured values include a measured value S_{T-1} corresponding to a time point T−1, a measured value S_{T-2} corresponding to a time point T−2, and a measured value S_{T-3} corresponding to a time point T−3, T, T−1, T−2, and T−3 represent four consecutive time points according to a sampling period of the sensor, the proportional term is based on S_{T}, the integral term is based on an average of S_{T}, S_{T-1}, S_{T-2}, and S_{T-3}, and the differential term is based on S_{T}−S_{T-1}.

Clause 24. The computing device of any of clauses 18 to 23, wherein the at least one processor configured to obtain the first measured value of the measured object is further configured to: obtain, from a sensing transducer of the sensor, a raw value corresponding to the first power consumption level; and adjust the raw value based on a set of calibration coefficients to obtain the first measured value.

Clause 25. The computing device of clause 24, wherein the at least one processor is further configured to: configure the sensing transducer of the sensor based on a set of offset correction coefficients.

Clause 26. The computing device of any of clauses 18 to 25, wherein: the measured object is a circuit block, and the first power consumption level corresponds to a current level of the circuit block.

Clause 27. A computing device, comprising: a memory; and at least one processor communicatively coupled to the memory, the at least one processor configured to: obtain, from a sensor, a first measured value of a measured object, the first measured value corresponding to a first power consumption level of the measured object at a first time point; obtain, from the sensor, one or more second measured values of the measured object, the one or more second measured values corresponding to one or more second power consumption levels of the measured object at one or more second time points earlier than the first time point; obtain, from measurement processing circuitry, a corrected value that is determined based on the first measured value and the one or more second measured values, the corrected value representing the first power consumption level of the measured object at the first time point; train a machine learning model for determining an updated set of measurement processing coefficients of the measurement processing circuitry, the machine learning model being trained based on training input data and training reference data, the training input data being based on the first measured value, the one or more second measured values, the corrected value, a value derived from the measured values, or a combination thereof, and the training reference data being based on a ground truth value of the first power consumption level; and configure the measurement processing circuitry based on the updated set of measurement processing coefficients after the machine learning model is trained based on the training input data and the training reference data.

Clause 28. The computing device of clause 27, wherein the at least one processor is further configured to: obtain measurement data from one or more other sensors, wherein the training input data is further based on at least a portion of the measurement data.

Clause 29. The computing device of any of clauses 27 to 28, wherein the machine learning model is arranged based on a weighted combination of a proportional term, an integral term, and a differential term, the proportional term is determined based on the first measured value, the integral term is determined based on the first measured value and the one or more second measured values, and the differential term is determined based on the first measured value and at least one of the one or more second measured values.

Clause 30. The computing device of clause 29, wherein the machine learning model is arranged based on an expression of Rᵢ=I_{Pi}*W_{P}+I_{Ii}*W_{I}+I_{Di}*W_{D}+W_{B}+Eᵢ, where: Rᵢ representing the ground truth value corresponding to the first time point, I_{Pi} representing the proportional term, I_{Ii} representing the integral term, I_{Di} representing the differential term, W_{P} representing a first weight for the proportional term, W_{I} representing a second weight for the integral term, W_{D} representing a third weight for the differential term, W_{B} representing a correction offset weight, and Eᵢ representing a constant bias error correction offset to be determined through training of the machine learning model.

Clause 31. The computing device of any of clauses 29 to 30, wherein the first measured value at the first time point T is denoted as S_{T}, the one or more second measured values include a measured value S_{T-1} corresponding to a time point T−1, a measured value S_{T-2} corresponding to a time point T−2, and a measured value S_{T-3} corresponding to a time point T−3, T, T−1, T−2, and T−3 represent four consecutive time points according to a sampling period of the sensor, the proportional term is based on S_{T}, the integral term is based on an average of S_{T}, S_{T-1}, S_{T-2}, and S_{T-3}, and the differential term is based on S_{T}−S_{T-1}.

Clause 32. The computing device of any of clauses 27 to 31, wherein the at least one processor is further configured to: obtain, from a sensing transducer of the sensor, a raw value corresponding to the first power consumption level; and determine a set of calibration coefficients based on the raw value and the ground truth value of the first power consumption level, the set of calibration coefficients enabling a sensor controller of the sensor to adjust the raw value based on the set of calibration coefficients to obtain the first measured value.

Clause 33. The computing device of clause 32, wherein the at least one processor is further configured to: configure the sensor controller of the sensor based on the updated set of calibration coefficients.

Clause 34. The computing device of any of clauses 27 to 33, wherein: the measured object is a circuit block, and the first power consumption level corresponds to a current level of the circuit block.

Clause 35. A computing device, comprising: means for obtaining, from a sensor, a first measured value of a measured object, the first measured value corresponding to a first power consumption level of the measured object at a first time point; means for obtaining, from the sensor, one or more second measured values of the measured object, the one or more second measured values corresponding to one or more second power consumption levels of the measured object at one or more second time points earlier than the first time point; and means for determining a corrected value based on the first measured value and the one or more second measured values, the corrected value representing the first power consumption level of the measured object at the first time point.

Clause 36. The computing device of clause 35, further comprising: means for obtaining, from machine learning processing circuitry, a set of measurement processing coefficients, wherein the means for determining the corrected value comprises means for processing the first measured value and the one or more second measured values based on the set of measurement processing coefficients.

Clause 37. The computing device of clause 36, further comprising: means for outputting, to the machine learning processing circuitry, the first measured value, the one or more second measured values, the corrected value, or a combination thereof, wherein the first measured value, the one or more second measured values, the corrected value, or a combination thereof enable the machine learning processing circuitry to train a machine learning model for determining an updated set of measurement processing coefficients.

Clause 38. The computing device of any of clauses 35 to 37, wherein the means for determining the corrected value comprises: means for determining a proportional term based on the first measured value; means for determining an integral term based on the first measured value and the one or more second measured values; means for determining a differential term based on the first measured value and at least one of the one or more second measured values; and means for determining the corrected value based on a weighted combination of the proportional term, the integral term, and the differential term.

Clause 39. The computing device of clause 38, wherein the weighted combination of the proportional term, the integral term, and the differential term is calculated based on an expression of Oᵢ=I_{Pi}*W_{P}+I_{Ii}*W_{I}+I_{Di}*W_{D}+W_{B}, where: Oᵢ representing the corrected value corresponding to the first time point, I_{Pi} representing the proportional term, I_{Ii} representing the integral term, I_{Di} representing the differential term, W_{P} representing a first weight for the proportional term, W_{I} representing a second weight for the integral term, W_{D} representing a third weight for the differential term, and W_{B} represents a correction offset weight.

Clause 40. The computing device of any of clauses 38 to 39, wherein the first measured value at the first time point T is denoted as S_{T}, the one or more second measured values include a measured value S_{T-1} corresponding to a time point T−1, a measured value S_{T-2} corresponding to a time point T−2, and a measured value S_{T-3} corresponding to a time point T−3, T, T−1, T−2, and T−3 represent four consecutive time points according to a sampling period of the sensor, the proportional term is based on S_{T}, the integral term is based on an average of S_{T}, S_{T-1}, S_{T-2}, and S_{T-3}, and the differential term is based on S_{T}−S_{T-1}.

Clause 41. The computing device of any of clauses 35 to 40, wherein the means for obtaining the first measured value of the measured object comprises: means for obtaining, from a sensing transducer of the sensor, a raw value corresponding to the first power consumption level; and means for adjusting the raw value based on a set of calibration coefficients to obtain the first measured value.

Clause 42. The computing device of clause 41, further comprising: means for configuring the sensing transducer of the sensor based on a set of offset correction coefficients.

Clause 43. The computing device of any of clauses 35 to 42, wherein: the measured object is a circuit block, and the first power consumption level corresponds to a current level of the circuit block.

Clause 44. A computing device, comprising: means for obtaining, from a sensor, a first measured value of a measured object, the first measured value corresponding to a first power consumption level of the measured object at a first time point; means for obtaining, from the sensor, one or more second measured values of the measured object, the one or more second measured values corresponding to one or more second power consumption levels of the measured object at one or more second time points earlier than the first time point; means for obtaining, from measurement processing circuitry, a corrected value that is determined based on the first measured value and the one or more second measured values, the corrected value representing the first power consumption level of the measured object at the first time point; means for training a machine learning model for determining an updated set of measurement processing coefficients of the measurement processing circuitry, the training the machine learning model being based on training input data and training reference data, the training input data being based on the first measured value, the one or more second measured values, the corrected value, a value derived from the measured values, or a combination thereof, and the training reference data being based on a ground truth value of the first power consumption level; and means for configuring the measurement processing circuitry based on the updated set of measurement processing coefficients after the machine learning model is trained based on the training input data and the training reference data.

Clause 45. The computing device of clause 44, further comprising: means for obtaining measurement data from one or more other sensors, wherein the training input data is further based on at least a portion of the measurement data.

Clause 46. The computing device of any of clauses 44 to 45, wherein the machine learning model is arranged based on a weighted combination of a proportional term, an integral term, and a differential term, the proportional term is determined based on the first measured value, the integral term is determined based on the first measured value and the one or more second measured values, and the differential term is determined based on the first measured value and at least one of the one or more second measured values.

Clause 47. The computing device of clause 46, wherein the machine learning model is arranged based on an expression of Rᵢ=I_{Pi}*W_{P}+I_{Ii}*W_{I}+I_{Di}*W_{D}+W_{B}+Eᵢ, where: Rᵢ representing the ground truth value corresponding to the first time point, I_{Pi} representing the proportional term, I_{Ii} representing the integral term, I_{Di} representing the differential term, W_{P} representing a first weight for the proportional term, W_{I} representing a second weight for the integral term, W_{D} representing a third weight for the differential term, W_{B} representing a correction offset weight, and Eᵢ representing a constant bias error correction offset to be determined through the training the machine learning model.

Clause 48. The computing device of any of clauses 46 to 47, wherein the first measured value at the first time point T is denoted as S_{T}, the one or more second measured values include a measured value S_{T-1} corresponding to a time point T−1, a measured value S_{T-2} corresponding to a time point T−2, and a measured value S_{T-3} corresponding to a time point T−3, T, T−1, T−2, and T−3 represent four consecutive time points according to a sampling period of the sensor, the proportional term is based on S_{T}, the integral term is based on an average of S_{T}, S_{T-1}, S_{T-2}, and S_{T-3}, and the differential term is based on S_{T}−S_{T-1}.

Clause 49. The computing device of any of clauses 44 to 48, further comprising: means for obtaining, from a sensing transducer of the sensor, a raw value corresponding to the first power consumption level; and means for determining a set of calibration coefficients based on the raw value and the ground truth value of the first power consumption level, the set of calibration coefficients enabling a sensor controller of the sensor to adjust the raw value based on the set of calibration coefficients to obtain the first measured value.

Clause 50. The computing device of clause 49, further comprising: means for configuring the sensor controller of the sensor based on the updated set of calibration coefficients.

Clause 51. The computing device of any of clauses 44 to 50, wherein: the measured object is a circuit block, and the first power consumption level corresponds to a current level of the circuit block.

Clause 52. A non-transitory computer-readable medium storing computer-executable instructions that, when executed by a computing device, cause the computing device to: obtain, from a sensor, a first measured value of a measured object, the first measured value corresponding to a first power consumption level of the measured object at a first time point; obtain, from the sensor, one or more second measured values of the measured object, the one or more second measured values corresponding to one or more second power consumption levels of the measured object at one or more second time points earlier than the first time point; and determine, by measurement processing circuitry, a corrected value based on the first measured value and the one or more second measured values, the corrected value representing the first power consumption level of the measured object at the first time point.

Clause 53. The non-transitory computer-readable medium of clause 52, further comprising computer-executable instructions that, when executed by the computing device, cause the computing device to: obtain, from machine learning processing circuitry, a set of measurement processing coefficients, wherein the computer-executable instructions that, when executed by the computing device, cause the computing device to determine the corrected value further cause the computing device to process the first measured value and the one or more second measured values based on the set of measurement processing coefficients.

Clause 54. The non-transitory computer-readable medium of clause 53, further comprising computer-executable instructions that, when executed by the computing device, cause the computing device to: output, to the machine learning processing circuitry, the first measured value, the one or more second measured values, the corrected value, or a combination thereof, wherein the first measured value, the one or more second measured values, the corrected value, or a combination thereof enable the machine learning processing circuitry to train a machine learning model for determining an updated set of measurement processing coefficients of the measurement processing circuitry.

Clause 55. The non-transitory computer-readable medium of any of clauses 52 to 54, wherein the computer-executable instructions that, when executed by the computing device, cause the computing device to determine the corrected value further cause the computer device to: determine a proportional term based on the first measured value; determine an integral term based on the first measured value and the one or more second measured values; determine a differential term based on the first measured value and at least one of the one or more second measured values; and determine the corrected value based on a weighted combination of the proportional term, the integral term, and the differential term.

Clause 56. The non-transitory computer-readable medium of clause 55, wherein the weighted combination of the proportional term, the integral term, and the differential term is calculated based on an expression of Oᵢ=I_{Pi}*W_{P}+I_{Ii}*W_{I}+I_{Di}*W_{D}+W_{B}, where: Oᵢ representing the corrected value corresponding to the first time point, I_{Pi} representing the proportional term, I_{Ii} representing the integral term, I_{Di} representing the differential term, W_{P} representing a first weight for the proportional term, W_{I} representing a second weight for the integral term, W_{D} representing a third weight for the differential term, and W_{B} represents a correction offset weight.

Clause 57. The non-transitory computer-readable medium of any of clauses 55 to 56, wherein the first measured value at the first time point T is denoted as S_{T}, the one or more second measured values include a measured value S_{T-1} corresponding to a time point T−1, a measured value S_{T-2} corresponding to a time point T−2, and a measured value S_{T-3} corresponding to a time point T−3, T, T−1, T−2, and T−3 represent four consecutive time points according to a sampling period of the sensor, the proportional term is based on S_{T}, the integral term is based on an average of S_{T}, S_{T-1}, S_{T-2}, and S_{T-3}, and the differential term is based on S_{T}−S_{T-1}.

Clause 58. The non-transitory computer-readable medium of any of clauses 52 to 57, wherein the computer-executable instructions that, when executed by the computing device, cause the computing device to obtain the first measured value of the measured object further cause the computing device to: obtain, from a sensing transducer of the sensor, a raw value corresponding to the first power consumption level; and adjust the raw value based on a set of calibration coefficients to obtain the first measured value.

Clause 59. The non-transitory computer-readable medium of clause 58, further comprising computer-executable instructions that, when executed by the computing device, cause the computing device to: configure the sensing transducer of the sensor based on a set of offset correction coefficients.

Clause 60. The non-transitory computer-readable medium of any of clauses 52 to 59, wherein: the measured object is a circuit block, and the first power consumption level corresponds to a current level of the circuit block.

Clause 61. A non-transitory computer-readable medium storing computer-executable instructions that, when executed by a computing device, cause the computing device to: obtain, from a sensor, a first measured value of a measured object, the first measured value corresponding to a first power consumption level of the measured object at a first time point; obtain, from the sensor, one or more second measured values of the measured object, the one or more second measured values corresponding to one or more second power consumption levels of the measured object at one or more second time points earlier than the first time point; obtain, from measurement processing circuitry, a corrected value that is determined based on the first measured value and the one or more second measured values, the corrected value representing the first power consumption level of the measured object at the first time point; train a machine learning model for determining an updated set of measurement processing coefficients of the measurement processing circuitry, the machine learning model being trained based on training input data and training reference data, the training input data being based on the first measured value, the one or more second measured values, the corrected value, a value derived from the measured values, or a combination thereof, and the training reference data being based on a ground truth value of the first power consumption level; and configure the measurement processing circuitry based on the updated set of measurement processing coefficients after the machine learning model is trained based on the training input data and the training reference data.

Clause 62. The non-transitory computer-readable medium of clause 61, further comprising computer-executable instructions that, when executed by the computing device, cause the computing device to: obtain measurement data from one or more other sensors, wherein the training input data is further based on at least a portion of the measurement data.

Clause 63. The non-transitory computer-readable medium of any of clauses 61 to 62, wherein the machine learning model is arranged based on a weighted combination of a proportional term, an integral term, and a differential term, the proportional term is determined based on the first measured value, the integral term is determined based on the first measured value and the one or more second measured values, and the differential term is determined based on the first measured value and at least one of the one or more second measured values.

Clause 64. The non-transitory computer-readable medium of clause 63, wherein the machine learning model is arranged based on an expression of Rᵢ=I_{Pi}*W_{P}+I_{Ii}*W_{I}+I_{Di}*W_{D}+W_{B}+Eᵢ, where: Rᵢ representing the ground truth value corresponding to the first time point, I_{Pi} representing the proportional term, I_{Ii} representing the integral term, I_{Di} representing the differential term, W_{P} representing a first weight for the proportional term, W_{I} representing a second weight for the integral term, W_{D} representing a third weight for the differential term, W_{B} representing a correction offset weight, and Eᵢ representing a constant bias error correction offset to be determined through training of the machine learning model.

Clause 65. The non-transitory computer-readable medium of any of clauses 63 to 64, wherein the first measured value at the first time point T is denoted as S_{T}, the one or more second measured values include a measured value S_{T-1} corresponding to a time point T−1, a measured value S_{T-2} corresponding to a time point T−2, and a measured value S_{T-3} corresponding to a time point T−3, T, T−1, T−2, and T−3 represent four consecutive time points according to a sampling period of the sensor, the proportional term is based on S_{T}, the integral term is based on an average of S_{T}, S_{T-1}, S_{T-2}, and S_{T-3}, and the differential term is based on S_{T}−S_{T-1}.

Clause 66. The non-transitory computer-readable medium of any of clauses 61 to 65, further comprising computer-executable instructions that, when executed by the computing device, cause the computing device to: obtain, from a sensing transducer of the sensor, a raw value corresponding to the first power consumption level; and determine a set of calibration coefficients based on the raw value and the ground truth value of the first power consumption level, the set of calibration coefficients enabling a sensor controller of the sensor to adjust the raw value based on the set of calibration coefficients to obtain the first measured value.

Clause 67. The non-transitory computer-readable medium of clause 66, further comprising computer-executable instructions that, when executed by the computing device, cause the computing device to: configure the sensor controller of the sensor based on the updated set of calibration coefficients.

Clause 68. The non-transitory computer-readable medium of any of clauses 61 to 67, wherein: the measured object is a circuit block, and the first power consumption level corresponds to a current level of the circuit block.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general purpose processor, a digital signal processor (DSP), an ASIC, a field-programmable gate array (FPGA), or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, for example, a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers.

Combinations of the above should also be included within the scope of computer-readable media.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. A method of measurement correction, comprising:
obtaining, from a sensor, a first measured value of a measured object, the first measured value corresponding to a first power consumption level of the measured object at a first time point;
obtaining, from the sensor, one or more second measured values of the measured object, the one or more second measured values corresponding to one or more second power consumption levels of the measured object at one or more second time points earlier than the first time point; and
determining, by measurement processing circuitry, a corrected value based on the first measured value and the one or more second measured values, the corrected value representing the first power consumption level of the measured object at the first time point.

2. The method of claim 1, further comprising:
obtaining, from machine learning processing circuitry, a set of measurement processing coefficients,
wherein the determining the corrected value comprises processing the first measured value and the one or more second measured values based on the set of measurement processing coefficients.

3. The method of claim 2, further comprising:
outputting, to the machine learning processing circuitry, the first measured value, the one or more second measured values, the corrected value, a value derived from the measured values, or a combination thereof,
wherein the first measured value, the one or more second measured values, the corrected value, the value derived from the measured value, or a combination thereof enable the machine learning processing circuitry to train a machine learning model for determining an updated set of measurement processing coefficients of the measurement processing circuitry.

4. The method of claim 1, wherein the determining the corrected value comprises:
determining a proportional term based on the first measured value;
determining an integral term based on the first measured value and the one or more second measured values;
determining a differential term based on the first measured value and at least one of the one or more second measured values; and
determining the corrected value based on a weighted combination of the proportional term, the integral term, and the differential term.

5. The method of claim 4, wherein the weighted combination of the proportional term, the integral term, and the differential term is calculated based on an expression of
Oᵢ=I_{Pi}*W_{P}+I_{Ii}*W_{I}+I_{Di}*W_{D}+W_{B}, where:
Oᵢ representing the corrected value corresponding to the first time point,
I_{Pi} representing the proportional term,
I_{Ii} representing the integral term,
I_{Di} representing the differential term,
W_{P} representing a first weight for the proportional term,
W_{I} representing a second weight for the integral term,
W_{D} representing a third weight for the differential term, and
W_{B} represents a correction offset weight.

6. The method of claim 4, wherein
the first measured value at the first time point T is denoted as S_{T},
the one or more second measured values include a measured value S_{T-1} corresponding to a time point T−1, a measured value S_{T-2} corresponding to a time point T−2, and a measured value S_{T-3} corresponding to a time point T−3,
T, T−1, T−2, and T−3 represent four consecutive time points according to a sampling period of the sensor,
the proportional term is based on S_{T},
the integral term is based on an average of S_{T}, S_{T-1}, S_{T-2}, and S_{T-3}, and
the differential term is based on S_{T}−S_{T-1}.

7. The method of claim 1, wherein the obtaining the first measured value of the measured object comprises:
obtaining, from a sensing transducer of the sensor, a raw value corresponding to the first power consumption level; and
adjusting, by a sensor controller of the sensor, the raw value based on a set of calibration coefficients to obtain the first measured value.

8. The method of claim 7, further comprising:
configuring the sensing transducer of the sensor based on a set of offset correction coefficients.

9. The method of claim 1, wherein:
the measured object is a circuit block, and
the first power consumption level corresponds to a current level of the circuit block.

10. A method of measurement correction, comprising:
obtaining, from a sensor, a first measured value of a measured object, the first measured value corresponding to a first power consumption level of the measured object at a first time point;
obtaining, from the sensor, one or more second measured values of the measured object, the one or more second measured values corresponding to one or more second power consumption levels of the measured object at one or more second time points earlier than the first time point;
obtaining, from measurement processing circuitry, a corrected value that is determined based on the first measured value and the one or more second measured values, the corrected value representing the first power consumption level of the measured object at the first time point;
training a machine learning model for determining an updated set of measurement processing coefficients of the measurement processing circuitry,
the training the machine learning model being based on training input data and training reference data,
the training input data being based on the first measured value, the one or more second measured values, the corrected value, a value derived from the measured values, or a combination thereof, and
the training reference data being based on a ground truth value of the first power consumption level; and
configuring the measurement processing circuitry based on the updated set of measurement processing coefficients after the machine learning model is trained based on the training input data and the training reference data.

11. The method of claim 10, further comprising:
obtaining measurement data from one or more other sensors,
wherein the training input data is further based on at least a portion of the measurement data.

12. The method of claim 10, wherein
the machine learning model is arranged based on a weighted combination of a proportional term, an integral term, and a differential term,
the proportional term is determined based on the first measured value,
the integral term is determined based on the first measured value and the one or more second measured values, and
the differential term is determined based on the first measured value and at least one of the one or more second measured values.

13. The method of claim 12, wherein the machine learning model is arranged based on an expression of
Rᵢ=I_{Pi}*W_{P}+I_{Ii}*W_{I}+I_{Di}*W_{D}+W_{B}+Eᵢ, where:
Rᵢ representing the ground truth value corresponding to the first time point,
I_{Pi} representing the proportional term,
I_{Ii} representing the integral term,
I_{Di} representing the differential term,
W_{P} representing a first weight for the proportional term,
W_{I} representing a second weight for the integral term,
W_{D} representing a third weight for the differential term,
W_{B} representing a correction offset weight, and
Eᵢ representing a constant bias error correction offset to be determined through the training the machine learning model.

14. The method of claim 12, wherein
the first measured value at the first time point T is denoted as S_{T},
the one or more second measured values include a measured value S_{T-1} corresponding to a time point T−1, a measured value S_{T-2} corresponding to a time point T−2, and a measured value S_{T-3} corresponding to a time point T−3,
T, T−1, T−2, and T−3 represent four consecutive time points according to a sampling period of the sensor,
the proportional term is based on S_{T},
the integral term is based on an average of S_{T}, S_{T-1}, S_{T-2}, and S_{T-3}, and
the differential term is based on S_{T}−S_{T-1}.

15. The method of claim 10, further comprising:
obtaining, from a sensing transducer of the sensor, a raw value corresponding to the first power consumption level; and
determining a set of calibration coefficients based on the raw value and the ground truth value of the first power consumption level, the set of calibration coefficients enabling a sensor controller of the sensor to adjust the raw value based on the set of calibration coefficients to obtain the first measured value.

16. The method of claim 15, further comprising:
configuring the sensor controller of the sensor based on the updated set of calibration coefficients.

17. The method of claim 10, wherein:
the measured object is a circuit block, and
the first power consumption level corresponds to a current level of the circuit block.

18. A computing device, comprising:
a memory; and
at least one processor communicatively coupled to the memory, the at least one processor configured to:
obtain, from a sensor, a first measured value of a measured object, the first measured value corresponding to a first power consumption level of the measured object at a first time point;
obtain, from the sensor, one or more second measured values of the measured object, the one or more second measured values corresponding to one or more second power consumption levels of the measured object at one or more second time points earlier than the first time point; and
determine a corrected value based on the first measured value and the one or more second measured values, the corrected value representing the first power consumption level of the measured object at the first time point.

19. The computing device of claim 18, wherein the at least one processor is further configured to:
obtain, from machine learning processing circuitry, a set of measurement processing coefficients,
wherein the at least one processor configured to determine the corrected value is further configured to process the first measured value and the one or more second measured values based on the set of measurement processing coefficients.

20. The computing device of claim 19, wherein the at least one processor is further configured to:
output, to the machine learning processing circuitry, the first measured value, the one or more second measured values, the corrected value, or a combination thereof,
wherein the first measured value, the one or more second measured values, the corrected value, or a combination thereof enable the machine learning processing circuitry to train a machine learning model for determining an updated set of measurement processing coefficients.

21. The computing device of claim 18, wherein the at least one processor configured to determine the corrected value is further configured to:
determine a proportional term based on the first measured value;
determine an integral term based on the first measured value and the one or more second measured values;
determine a differential term based on the first measured value and at least one of the one or more second measured values; and
determine the corrected value based on a weighted combination of the proportional term, the integral term, and the differential term.

22. The computing device of claim 21, wherein the weighted combination of the proportional term, the integral term, and the differential term is calculated based on an expression of
Oᵢ=I_{Pi}*W_{P}+I_{Ii}*W_{I}+I_{Di}*W_{D}+W_{B}, where:
Oᵢ representing the corrected value corresponding to the first time point,
I_{Pi} representing the proportional term,
I_{Ii} representing the integral term,
I_{Di} representing the differential term,
W_{P} representing a first weight for the proportional term,
W_{I} representing a second weight for the integral term,
W_{D} representing a third weight for the differential term, and
W_{B} represents a correction offset weight.

23. The computing device of claim 21, wherein
the first measured value at the first time point T is denoted as S_{T},
the one or more second measured values include a measured value S_{T-1} corresponding to a time point T−1, a measured value S_{T-2} corresponding to a time point T−2, and a measured value S_{T-3} corresponding to a time point T−3,
T, T−1, T−2, and T−3 represent four consecutive time points according to a sampling period of the sensor,
the proportional term is based on S_{T},
the integral term is based on an average of S_{T}, S_{T-1}, S_{T-2}, and S_{T-3}, and
the differential term is based on S_{T}−S_{T-1}.

24. The computing device of claim 18, wherein the at least one processor configured to obtain the first measured value of the measured object is further configured to:
obtain, from a sensing transducer of the sensor, a raw value corresponding to the first power consumption level; and
adjust the raw value based on a set of calibration coefficients to obtain the first measured value.

25. A computing device, comprising:
a memory; and
at least one processor communicatively coupled to the memory, the at least one processor configured to:
obtain, from a sensor, a first measured value of a measured object, the first measured value corresponding to a first power consumption level of the measured object at a first time point;
obtain, from the sensor, one or more second measured values of the measured object, the one or more second measured values corresponding to one or more second power consumption levels of the measured object at one or more second time points earlier than the first time point;
obtain, from measurement processing circuitry, a corrected value that is determined based on the first measured value and the one or more second measured values, the corrected value representing the first power consumption level of the measured object at the first time point;
train a machine learning model for determining an updated set of measurement processing coefficients of the measurement processing circuitry,
the machine learning model being trained based on training input data and training reference data,
the training input data being based on the first measured value, the one or more second measured values, or the corrected value, or a combination thereof, and
the training reference data being based on a ground truth value of the first power consumption level; and
configure the measurement processing circuitry based on the updated set of measurement processing coefficients after the machine learning model is trained based on the training input data and the training reference data.

26. The computing device of claim 25, wherein the at least one processor is further configured to:
obtain measurement data from one or more other sensors,
wherein the training input data is further based on at least a portion of the measurement data.

27. The computing device of claim 25, wherein
the machine learning model is arranged based on a weighted combination of a proportional term, an integral term, and a differential term,
the proportional term is determined based on the first measured value,
the integral term is determined based on the first measured value and the one or more second measured values, and
the differential term is determined based on the first measured value and at least one of the one or more second measured values.

28. The computing device of claim 27, wherein the machine learning model is arranged based on an expression of
Rᵢ=I_{Pi}*W_{P}+I_{Ii}*W_{I}+I_{Di}*W_{D}+W_{B}+Eᵢ, where:
Rᵢ representing the ground truth value corresponding to the first time point,
I_{Pi} representing the proportional term,
I_{Ii} representing the integral term,
I_{Di} representing the differential term,
W_{P} representing a first weight for the proportional term,
W_{I} representing a second weight for the integral term,
W_{D} representing a third weight for the differential term,
W_{B} representing a correction offset weight, and
Eᵢ representing a constant bias error correction offset to be determined through training of the machine learning model.

29. The computing device of claim 27, wherein
the first measured value at the first time point T is denoted as S_{T},
the one or more second measured values include a measured value S_{T-1} corresponding to a time point T−1, a measured value S_{T-2} corresponding to a time point T−2, and a measured value S_{T-3} corresponding to a time point T−3,
T, T−1, T−2, and T−3 represent four consecutive time points according to a sampling period of the sensor,
the proportional term is based on S_{T},
the integral term is based on an average of S_{T}, S_{T-1}, S_{T-2}, and S_{T-3}, and
the differential term is based on S_{T}−S_{T-1}.

30. The computing device of claim 25, wherein the at least one processor is further configured to:
obtain, from a sensing transducer of the sensor, a raw value corresponding to the first power consumption level; and
determine a set of calibration coefficients based on the raw value and the ground truth value of the first power consumption level, the set of calibration coefficients enabling a sensor controller of the sensor to adjust the raw value based on the set of calibration coefficients to obtain the first measured value.
